(19) United States
(12) Patent Application Publication
(10) Pub. No.: US 2023/0006167 A1
(43) Pub. Date: Jan. 5, 2023

(54) ORGANIC ELECTROLUMINESCENCE ELEMENT

(71) Applicant: CANON KABUSHIKI KAISHA, Tokyo (JP)

(72) Inventors: Itaru Takaya, Kanagawa (JP); Satoru Shiobara, Kanagawa (JP)

(21) Appl. No.: 17/831,331

(22) Filed: Jun. 2, 2022

(30) Foreign Application Priority Data
Jun. 8, 2021 (JP) 2021-095619

(51) Int. Cl. H01L 51/50; H01L 27/32

(52) U.S. Cl. CPC H01L 51/5092; H01L 27/3234; H01L 51/504

(57) ABSTRACT

A layered type organic electroluminescence element including two organic electroluminescence layers disposed between a positive electrode and a negative electrode with an intermediate layer interposed therebetween, wherein the intermediate layer contains an alkali metal compound, a reduced form of the alkali metal compound, and a metal element of group II of the periodic table.

### BACKGROUND OF THE INVENTION

### Field of the Invention

The present disclosure relates to an organic electroluminescence element which is a light emitting element and equipment and apparatus which include the element.

### Description of the Related Art

An organic electroluminescence (EL) element is a light emitting element which emits light by energizing an organic EL layer including a pair of electrodes and a light emitting layer interposed between the pair of electrodes. In recent years, full-color light emitting arrays in which a white light emitting organic EL element and red, green, and blue color filters are combined have been developed. The white light emitting organic EL elements are roughly divided into a single-layer type organic EL element in which light emitting dopants, each emitting red, green, or blue light, are included together in an organic EL layer so as to obtain white light emission and a layered type organic EL element in which organic EL layers, each emitting red, green, or blue light, are stacked. Regarding the layered type organic EL element, since a plurality of organic EL layers are connected in series, a configuration in which an intermediate layer called an electric charge generation layer or an intermediate electrode layer is interposed between two organic EL layers is known. Regarding the white light emitting organic EL element, since painting is not performed on a pixel basis, when the intermediate layer has low electrical resistance, adjoining pixels emit light through the intermediate layer. Therefore, intermediate layers having high resistance have been developed.

Japanese Patent Laid-Open No. 2003-45676 (PTL 1) discloses a configuration in which an organic compound doped with a conductive organic compound or an alkali metal is used as the intermediate layer. In addition, Japanese Patent Laid-Open No. 2015-518287 (PTL 2) discloses that a layered structure of an organic compound layer doped with an alkali metal compound and an organic compound layer doped with a metal element of group II of the periodic table is included.

Regarding the organic EL element disclosed in PTL 1, an alkali metal is used for the intermediate layer. However, there is a disadvantage that the alkali metal tends to react with moisture in air and is hard to handle. On the other hand, regarding the organic EL element disclosed in PTL 2, an organic compound layer doped with an alkali metal compound which is easy to handle is formed as the intermediate layer, and an organic compound layer doped with a metal of group II is stacked. In such an instance, it is conjectured that the alkali metal compound is reduced by the metal of group II so as to realize the electron injection performance. In this regard, since the organic compound doped with the metal of group II is used, the intermediate layer has high resistance compared with the instance in which a metal element is used alone.

In particular, an alkali metal can be used for injecting electrons into the organic EL layer, but the alkali metal tends to react with moisture in air and is hard to handle. Consequently, a layer of an alkali metal compound such as lithium fluoride or a lithium-quinolinol complex which is easy to handle is formed, subsequently, a metal such as aluminum or a metal of group II which has a reducing property is vapor-deposited so as to reduce a portion of the alkali metal compound due to heat during vapor deposition and to realize the electron injection performance. In this method, the adhesiveness between the alkali metal compound layer and the metal layer having a reducing property is important. Aluminum has high adhesiveness to the alkali metal compound layer but has low electrical resistance and is unsuitable for the intermediate layer desired to have high resistance. In this regard, when a metal of group II is vapor-deposited alone, the adhesiveness to the underlying layer is low and the film forming performance is low. Therefore, when the metal of group II is used for a negative electrode or the like, to enhance the adhesiveness to the underlying layer, vapor co-deposition with silver or the like is frequently performed. However, a layer resulting from vapor co-deposition of the metal of group II and silver has low electrical resistance and is unsuitable for the intermediate layer desired to have high resistance.

In PTL 2, high adhesiveness between organic compound layers is exploited, and the adhesiveness is enhanced by stacking an organic compound layer of an organic compound doped with an alkali metal compound and an organic compound layer of an organic compound doped with a metal of group II. However, since the compatibility between the organic compound and the metal of group II is low, even when the organic compound and the metal of group II are subjected to vapor co-deposition, the metal of group II is not readily taken into the organic compound layer. Consequently, the metal compound in the underlying organic compound layer is not readily reduced, and there is a concern that the electron injection performance is not limited to being sufficiently realized.

### SUMMARY OF THE INVENTION

The present disclosure was realized in consideration of the above-described disadvantages and provides a layered type organic EL element including an intermediate layer exerting favorable electron injection performance by using an easy-to-treat alkali metal compound.

First, the present disclosure provides an organic electroluminescence element including a pair of electrodes and at least two organic electroluminescence layers that are disposed between the pair of electrodes and that are stacked with an intermediate layer interposed therebetween, wherein the intermediate layer contains an alkali metal compound, a reduced form of the alkali metal compound, and a metal element of group II of the periodic table.

Second, the present disclosure provides an exposure light source, a display apparatus, an imaging apparatus, an illumination apparatus, and a mobile unit, which include the organic electroluminescence element according to the present disclosure.

Further features of the present disclosure will become apparent from the following description of exemplary embodiments with reference to the attached drawings.

### BRIEF DESCRIPTION OF THE DRAWINGS

FIG. 1 is a schematic sectional view in the thickness direction illustrating the configuration of an organic EL element according to the present disclosure.

FIG. 2 is a schematic sectional view in the thickness direction illustrating the configuration of a favorable embodiment of the organic EL element according to the present disclosure.

FIGS. 3A to 3C are schematic diagrams illustrating the configuration of an embodiment of an exposure light source according to the present disclosure.

FIGS. 4A and 4B are schematic sectional views in the thickness direction illustrating the pixel configuration of an embodiment of a display apparatus according to the present disclosure.

FIG. 5 is an exploded perspective view illustrating the entire configuration of an embodiment of the display apparatus according to the present disclosure.

FIGS. 6A and 6B are schematic front views illustrating another embodiment of the display apparatus according to the present disclosure.

FIGS. 7A and 7B are schematic front views illustrating embodiments of an imaging apparatus and electronic equipment, respectively, according to the present disclosure.

FIG. 8 is a schematic exploded perspective view illustrating an embodiment of an illumination apparatus according to the present disclosure.

FIG. 9 is a schematic perspective view illustrating an embodiment of a mobile unit according to the present disclosure.

FIGS. 10A and 10B are schematic perspective views illustrating the configuration of glasses including the display apparatus according to the present disclosure.

FIGS. 11A and 11B are graphs illustrating the voltage-current characteristics of organic EL elements of example 1 and example 2, respectively, according to the present disclosure.

FIGS. 12A and 12B are graphs illustrating the voltage-current characteristics of organic EL elements of comparative example 1 and comparative example 2, respectively, according to the present disclosure.

FIGS. 13A and 13B are graphs illustrating the voltage-current characteristics of organic EL elements of comparative example 3 and comparative example 4, respectively, according to the present disclosure.

### DESCRIPTION OF THE EMBODIMENTS

An organic electroluminescence element according to the present disclosure (hereafter referred to as an “organic EL element”) is a layered type organic EL element including at least two organic electroluminescence layers (hereafter referred to as “organic EL layers”) between a pair of electrodes. In this regard, an intermediate layer is interposed between the two organic EL layers, and the intermediate layer contains an alkali metal compound, a reduced form of the alkali metal compound, and a metal element of group II of the periodic table (hereafter referred to as “metal of Group II”).

The configuration of an EL element according to the present disclosure will be described below in detail based on an example of a favorable embodiment with reference to the drawings. However, the configuration, relative arrangement, and the like described in the embodiment are not intended to limit the scope of the present disclosure, unless otherwise specified.

### Organic EL Element

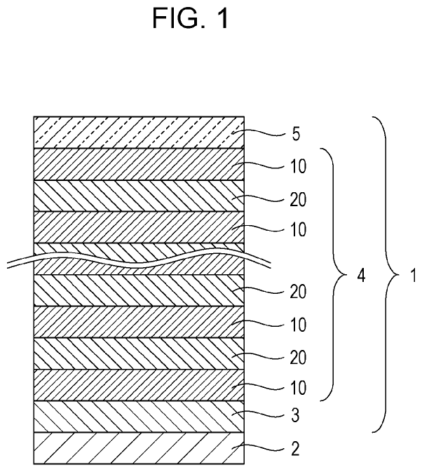

FIG. 1 is a schematic sectional view in the thickness direction (stacking direction) illustrating the configuration of an organic EL element according to the present disclosure. In the drawing, reference 1 denotes an organic EL element, reference 2 denotes a substrate, reference 3 denotes a positive electrode, reference 4 denotes an organic compound layer, reference 5 denotes a negative electrode, reference 10 denotes an organic EL layer, and reference 20 denotes an intermediate layer. In this regard, the organic compound layer 4 according to the present disclosure also includes layers, such as the intermediate layer 20, not containing an organic compound, but, for the sake of convenience, a multilayer body interposed between the positive electrode 3 and the negative electrode 5 is referred to as an “organic compound layer” in the present specification.

As illustrated in FIG. 1, the organic EL element 1 according to the present disclosure includes the organic compound layer 4 in which a plurality of organic EL layers 10 are stacked with the intermediate layer 20 interposed therebetween. In the organic EL element 1 according to the present disclosure, three organic EL layers 10 that emit red, green, and blue colors respectively may be included so as to emit white light in combination, or two organic EL layers 10 in which one emits two colors of red and green and the other emits a color of blue may be included so as to emit white light in combination. In addition, a plurality of organic EL layers 10 may have the same emission color so as to obtain a plurality of times of light emission and to realize high luminance. For example, when the organic EL layers 10 are two layers, obtained light emission is twice the light emission in the instance in which the organic EL layer 10 is a single layer.

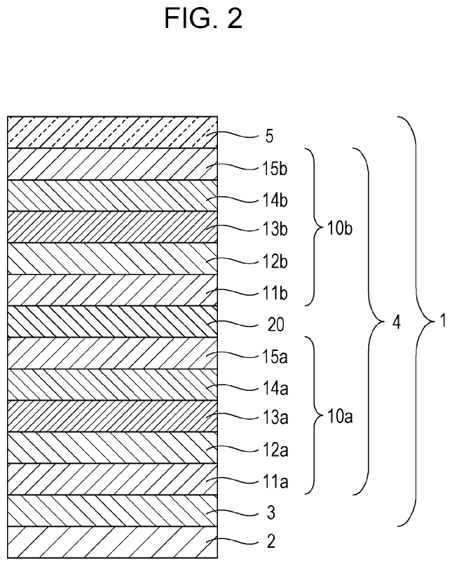

In the present disclosure, the organic EL layers 10 may be three or more layers, but the voltage applied between the electrodes is increased and the heat generation quantity of the element is increased. Therefore, the organic EL layers 10 can be composed of two layers. FIG. 2 is a schematic sectional view in the thickness direction illustrating the configuration of an embodiment in which the organic EL layers 10 are composed of two layers. In the following explanations, for the sake of convenience, a positive-electrode-side organic EL layer 10a is referred to as a first organic EL layer, and a negative-electrode-side organic EL layer 10b is referred to as a second organic EL layer. In this regard, the positions of the positive electrode 3 and the negative electrode 5 may be exchanged. However, as described below, when electron injection layers 15a and 15b are composed of an alkali metal compound, to reduce the alkali metal compound, the positive electrode 3 may be located near the substrate 2 and the layers may be formed successively from the positive electrode 3 to the negative electrode 5.

The intermediate layer 20 according to the present disclosure is a vapor co-deposition layer formed by subjecting the alkali metal compound and the metal of group II to vapor co-deposition. The alkali metal compound used for the intermediate layer 20 according to the present disclosure is a substance such as a halide, an oxide, a carbonate, or an organic coordination compound in which an alkali metal forms a positive ion and is bonded to a negative ion. In contrast to the alkali metal, the alkali metal compound is a substance which does not vigorously react with moisture in air, which is stable even in air, and which is easy to handle. In addition, the alkali metal compound is an essentially insulating substance due to being an ionic substance and does not exert electron injection performance without modification. When such an alkali metal compound is made into a film, and a metal such as aluminum (Al) or a metal of group II having a reducing property is vapor-deposited thereon, a portion of the alkali metal compound is reduced and the electron injection performance is realized. However, since Al has low electrical resistance, a disadvantage that adjoining pixels emit light through the intermediate layer occurs. When the metal of group II is vapor-deposited alone, since the adhesiveness to the underlying layer is low, a film is not readily formed, and vapor co-deposition with silver (Ag) or the like having high adhesiveness to the underlying layer is necessary. However, since Ag has low electrical resistance in the same manner akin to Al, a disadvantage that adjoining pixels emit light through the intermediate layer occurs. It is known that the resistivity of Al at 0° C. is 2.50×10⁻⁸ Ωm and that the resistivity of Ag at 0° C. is 1.47×10⁻⁸ Ωm. Therefore, the resistance tends to be lower than, for example, 3.94×10⁻⁸ Ωm of magnesium (Mg) classified in the metal of group II.

In the present disclosure, since reduction is performed without using Al and Ag, the alkali metal compound can be subjected to vapor co-deposition with the metal of group II so as to reduce the alkali metal compound during vapor deposition. When the alkali metal compound is subjected to vapor co-deposition with the metal of group II, a portion of the alkali metal compound is reduced by the metal of group II, and the electron injection performance is realized. In this regard, the intermediate layer 20 according to the present disclosure has high electrical resistance since the alkali metal compound which is an insulating substance, a reduced form of the alkali metal compound, and the metal of group II having high resistance in spite of being a metal are mixed in the layer. When the intermediate layer 20 is formed by vapor co-deposition of the alkali metal compound and the metal of group II, the intermediate layer 20 composed of only the alkali metal compound, the reduced form of the alkali metal compound, and the metal of group II is obtained.

In the present disclosure, the organic EL layers 10a and 10b include at least light emitting layers 13a and 13b, respectively. Each of the light emitting layers 13a and 13b may have a configuration in which a plurality of light emitting layers are stacked or a single-layer configuration, may be a two-color light emitting layer containing two color light emitting dopants, or may be a white light emitting layer containing three color light emitting dopants, as described above.

In this regard, as illustrated in FIG. 2, the organic EL layers 10a and 10b may include hole injection layers 11a and 11b, respectively, and hole transport layers 12a and 12b, respectively, nearer than the light emitting layers 13a and 13b, respectively, to the positive electrode 3 and may include electron transport layers 14a and 14b, respectively, and electron injection layers 15a and 15b, respectively, nearer than the light emitting layers 13a and 13b, respectively, to the negative electrode 5. Further, each may include an electron block layer and a hole block layer, as the situation demands.

In the present disclosure, the metal of group II contained in the intermediate layer 20 is preferably 75% by volume or less. The content of the metal of group II being more than 75% by volume is not favorable, since the resistance of the intermediate layer 20 is reduced, and a disadvantage that adjoining pixels emit light through the intermediate layer 20 tends to occur.

In this regard, to reduce the alkali metal compound, the content of the metal of group II is preferably 30% by volume or more. The content of the metal of group II is controlled by the vapor deposition rate during vapor deposition of the alkali metal compound and the metal of group II.

In the present disclosure, the alkali metal compound constituting the intermediate layer 20 is an ionic compound of lithium (Li), potassium (K), sodium (Na), rubidium (Rb), or cesium (Cs). Of these, a Li compound is favorable since the amount of substance is the smallest due to Li having a smallest atomic weight and since the vapor deposition temperature tends to be low, and a lithium halide or a lithium-quinolinol complex (Liq) is favorable. The halide of the alkali metal compound and Liq are favorable since the vapor deposition temperature is low. The lithium halide can be lithium fluoride (LiF). In addition, potassium fluoride (KF) can also be used. Of the halides, a fluoride is favorable since the amount of substance is small and since the vapor deposition temperature is low, and LiF is the most favorable as the alkali metal compound used for the present disclosure.

The vapor deposition temperature of the Cs compound tends to be higher than the vapor deposition temperature of the Li compound. However, the Cs compound is favorable due to having high electron injection performance. In addition, cesium carbonate (Cs₂CO₃) can be a vapor deposition material since the vapor deposition temperature is lower than that of the other cesium compounds and water is not readily contained due to low deliquescency.

In the present disclosure, the metal of group II constituting the intermediate layer 20 is any one of beryllium (Be), magnesium (Mg), calcium (Ca), strontium (Sr), and barium (Ba). It is conjectured that each of these metals of group II has a property of being able to reduce an alkali metal compound when being vapor-deposited on the alkali metal compound. However, the electron injection performance of the intermediate layer 20 differs in accordance with the combination of the alkali metal compound and the metal of group II, and Mg, Ca, and Sr provides favorable electron injection performance. Of these, Mg is the most favorable due to having the lowest melting point, low price, nontoxicity, and stability in air.

In the present disclosure, the first organic EL layer 10a located nearer than the intermediate layer 20 to the positive electrode 3 can include the electron injection layer 15a in contact with the intermediate layer 20, and the electron injection layer 15a can be an individual vapor-deposition layer of the alkali metal compound constituting the intermediate layer 20. When the electron injection layer 15a is formed of the alkali metal compound, and, thereafter, the intermediate layer 20 is formed by subjecting the alkali metal compound and the metal of group II to vapor co-deposition, a portion of the alkali metal compound of the electron injection layer 15a is reduced during vapor deposition of the intermediate layer 20, and the electron injection performance of the electron injection layer 15a is realized. That is, the electron injection layer 15a becomes a layer containing the alkali metal compound and a reduced form of the alkali metal compound.

Since the intermediate layer 20 according to the present disclosure exerts the electron injection performance into the first organic EL layer 10a, the electron injection layer 15a is not limited to being necessary. However, the electron injection layer 15a in contact with the intermediate layer 20 being included and the intermediate layer 20 and the electron injection layer 15a being formed by using the same alkali metal compound are a favorable embodiment. In such an instance, the adhesiveness between the intermediate layer 20 and the electron injection layer 15a is high, and, in addition to the electron injection performance of the intermediate layer 20, the electron injection performance into the electron transport layer 14a and the light emitting layer 13a is further enhanced due to the reduced form of the alkali metal compound contained in the electron injection layer 15a.

In addition, in the present disclosure, it was found that even when the electron injection layer 15a is included, the combination of the alkali metal compound and the metal of group II in the intermediate layer 20 readily realizes the electron injection performance compared with the combination of an organic compound and the metal of group II. It is conjectured that this is caused by the combination of the alkali metal compound and the metal of group II having higher compatibility than the combination of the organic compound and the metal of group II and being easily formed as a mixture film during vapor co-deposition.

In the present disclosure, the second organic EL layer 10b located nearer than the intermediate layer 20 to the negative electrode 5 can include the hole injection layer 11b in contact with the intermediate layer 20. Since the intermediate layer 20 contains the reduced form of the alkali metal compound and the metal of group II, the ionization potential is reduced, and the hole injection performance from the metal having a low ionization potential into the hole transport layer 12b and the light emitting layer 13b is low. Therefore, the hole injection layer 11b in contact with the intermediate layer 20 can be included. Regarding the material constituting the hole injection layer 11b, known materials for injecting the hole from the positive electrode into the hole transport layer in the related art are used, and organic compounds having a cyano group as denoted by HT16 to HT19 described later, molybdenum oxide, phthalocyanines, and the like are used.

As illustrated in FIG. 1 and FIG. 2, the organic EL element 1 according to the present disclosure is disposed on the substrate 2. Regarding the substrate 2, any one of quartz, glass, silicon wafer, resin, metal, and the like may be used. The substrate 2 may be provided with switching elements, such as a transistor, and conductive lines, and may be provided with an insulating layer thereon. There is no particular limitation regarding the material used for forming the insulating layer provided that the material is capable of forming a contact hole to ensure conduction between the positive electrode 3 and the conductive line and that insulation from an unconnected conductive line is ensured.

For example, resins such as a polyimide, silicon oxide, and silicon nitride may be used.

It is favorable that the constituent material of the positive electrode 3 has as large a work function as possible. Examples of the usable material include simple metals, such as gold, platinum, silver copper, nickel, palladium, titanium, cobalt, selenium, vanadium, and tungsten, mixtures containing these, alloys of combination of these, and metal oxides, such as tin oxide, zinc oxide, indium oxide, indium tin oxide (ITO), and indium zinc oxide. In addition, conductive polymers, such as polyanilines, polypyrroles, and polythiophenes, may be used.

One of these electrode materials may be used alone, or at least two types may be used in combination. The positive electrode 3 may be composed of a single layer or may be composed of a plurality of layers. When being used as a reflection electrode, for example, chromium, aluminum, silver, titanium, tungsten, and molybdenum, and alloys, oxides, nitrides, and layered bodies of these may be used. When being used as a transparent electrode, for example, oxide transparent conductive layers of indium tin oxide (ITO), indium zinc oxide, and the like may be used, but the material is not limited to these.

Photolithography may be used for forming the electrode.

The organic EL element 1 according to the present disclosure includes at least the first organic EL layer 10a and the second organic EL layer 10b with the intermediate layer 20 interposed therebetween. The first organic EL layer 10a and the second organic EL layer 10b may be formed by using the same material. In addition, three or more layers may be stacked, for example, a third organic EL layer may be further stacked. The materials for forming these will be described below.

In the first organic EL layer 10a nearer to the positive electrode 3, a material that enables hole injection from the positive electrode 3 to be facilitated is favorably used for the hole injection layer 11a disposed in contact with the positive electrode 3, and the material akin to that used for the hole injection layer 11b in contact with the intermediate layer 20, as described above, may be used. That is, organic compounds having a cyano group as denoted by HT16 to HT19 described later, molybdenum oxide, phthalocyanines, and the like are used.

Regarding the hole transport layers 12a and 12b, a material having high hole mobility is favorable to enable the injected holes to be transported to the light emitting layers 13a and 13b. In addition, to suppress deterioration of the film quality, such as crystallization, from occurring in the organic EL element 1, a material having a high glass transition temperature is favorable. Examples of the low-molecular-weight material and the high-molecular-weight material that have high hole mobility include triarylamine derivatives, arylcarbazole derivatives, phenylenediamine derivatives, stilbene derivatives, phthalocyanine derivatives, porphyrin derivatives, poly(vinylcarbazole), poly(thiophene), and other conductive polymers. In this regard, the materials akin to the material for forming the hole injection layers 11a and 11b may be used.

Specific examples HT1 to HT19 of the material used for forming the hole injection layers 11a and 11b and the hole transport layers 12a and 12b are described below, but the material is not limited to these.

An electron block layer (not illustrated in the drawing) may be included between the hole transport layer 12a and the light emitting layer 13a and between the hole transport layer 12b and the light emitting layer 13b, and when the electron block layers are formed, the same material may be used. The electron blocking material can be HT7 and HT8 to HT12 which have a carbazole group. A carbazole group being included deepens HOMO, enables levels in which HOMO is deepened in the order of the hole transport material, the hole blocking material, and the light emitting layer in a stepped configuration to be formed, and enables the holes to be injected into the light emitting layers 13a and 13b at a low voltage.

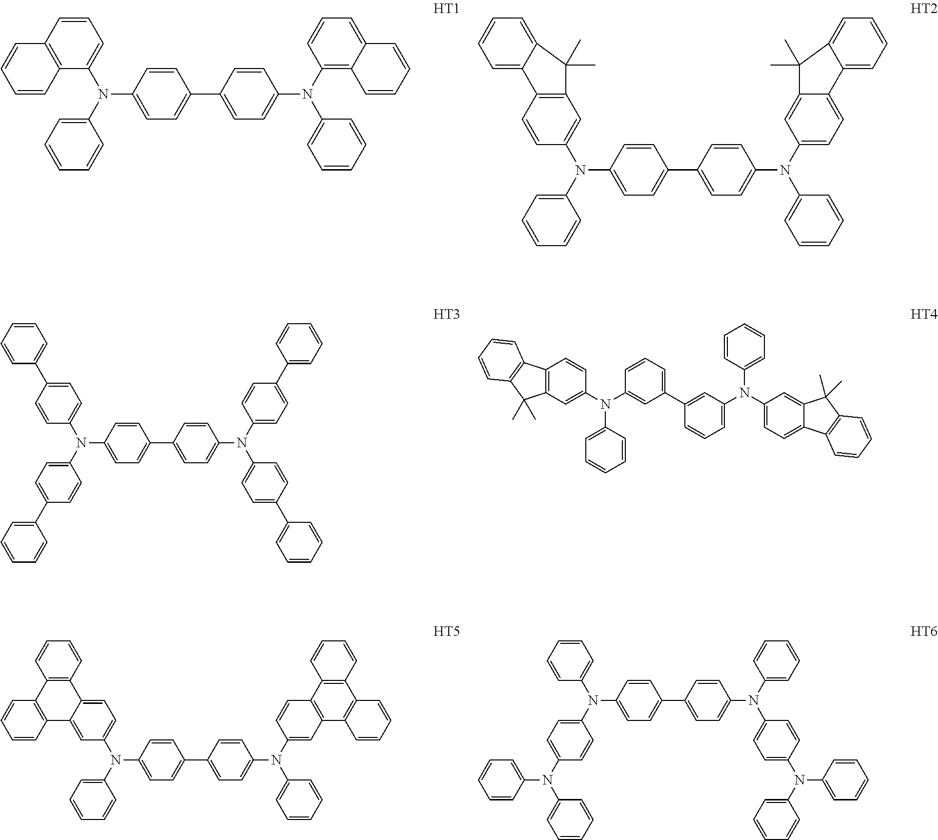

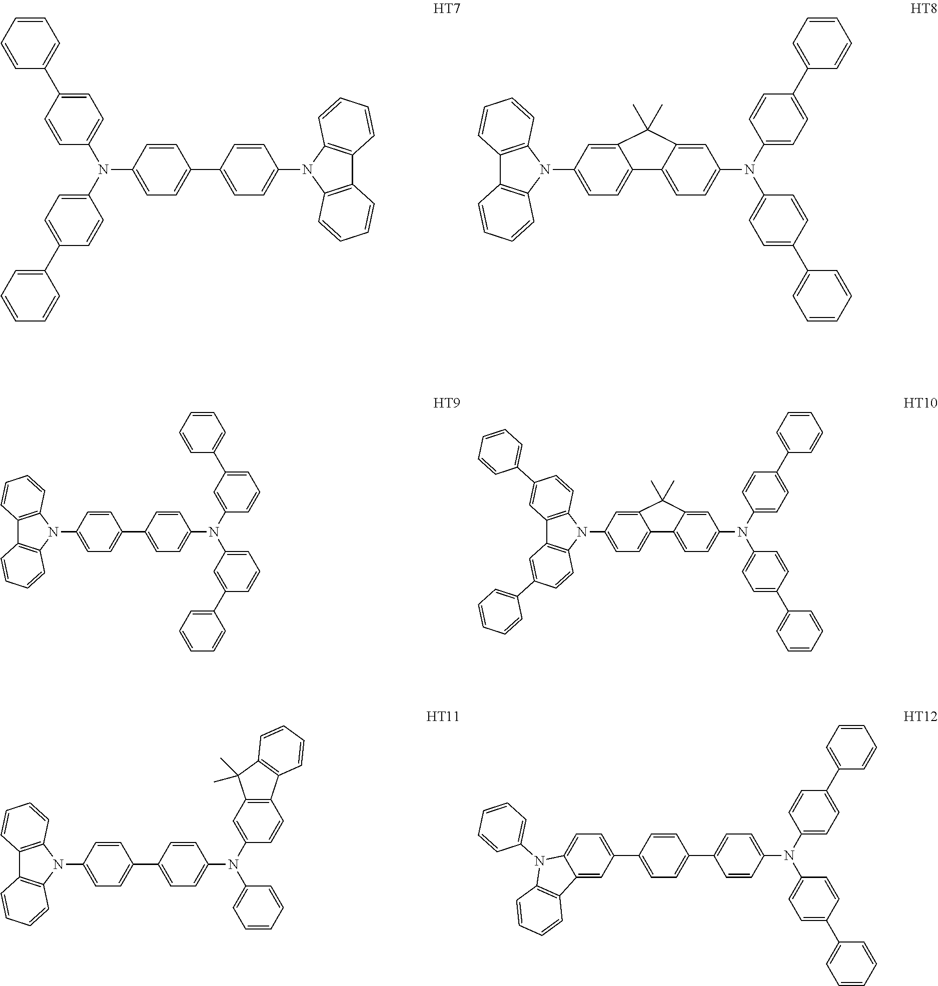

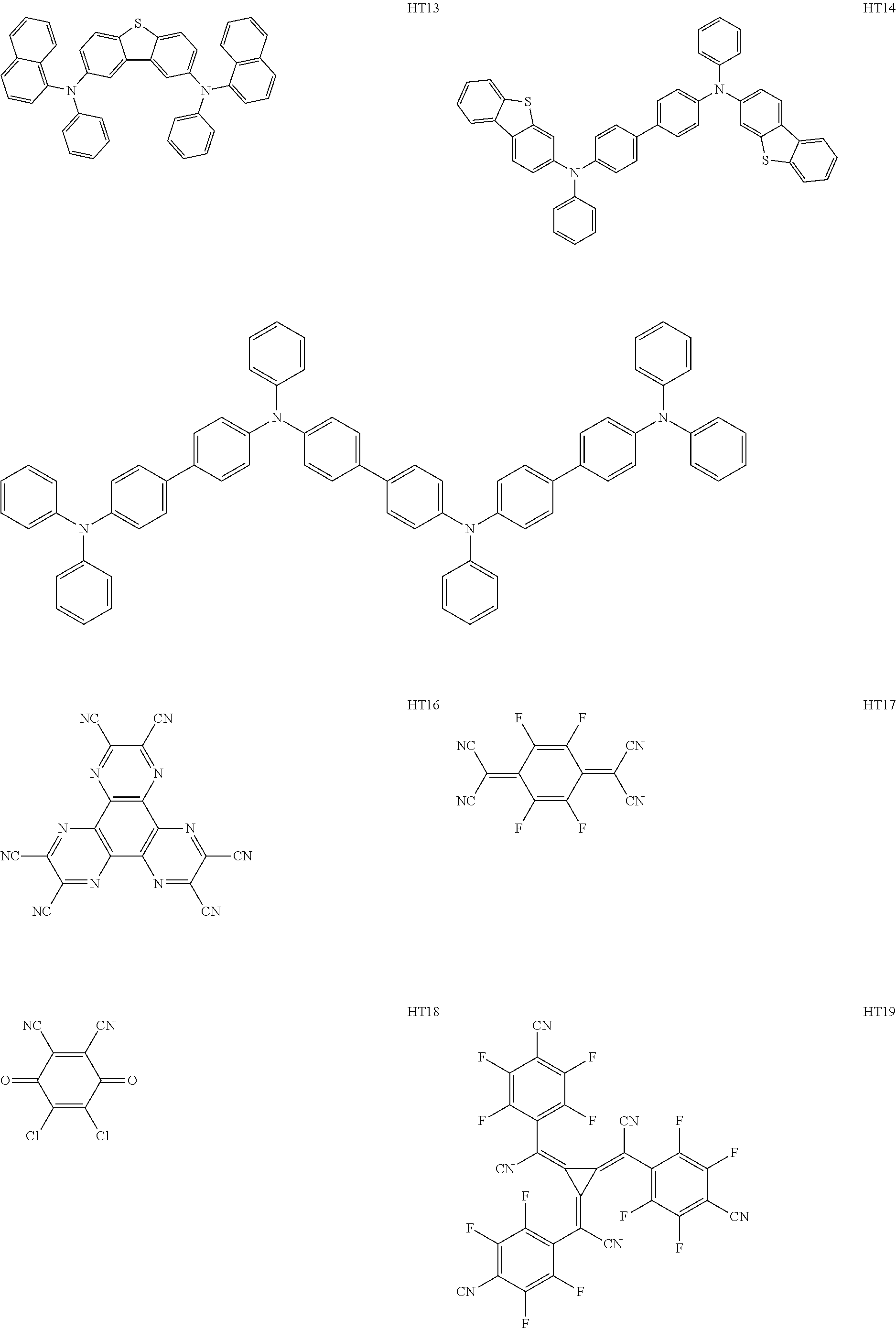

The light emitting layers 13a and 13b can have a configuration in which a host material contains a light emitting dopant, and specific examples EM1 to EM40 of the host material are as described below.

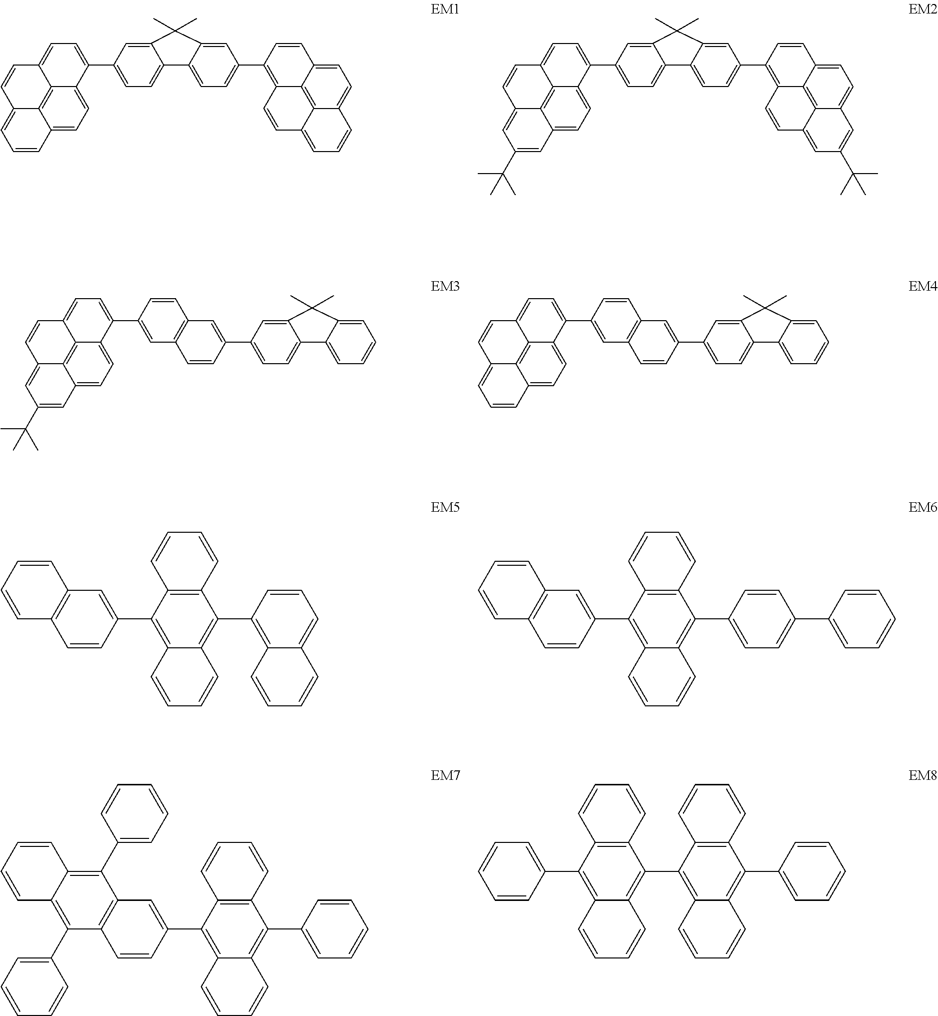

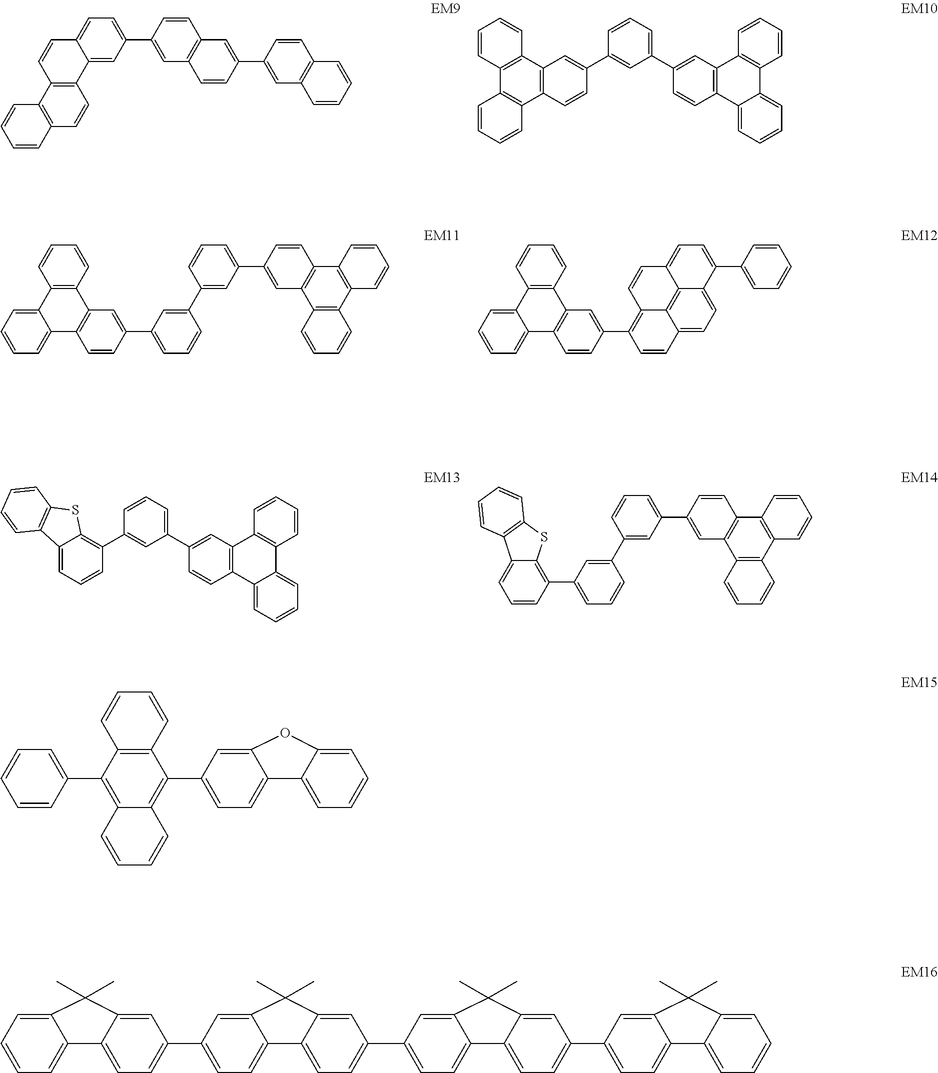

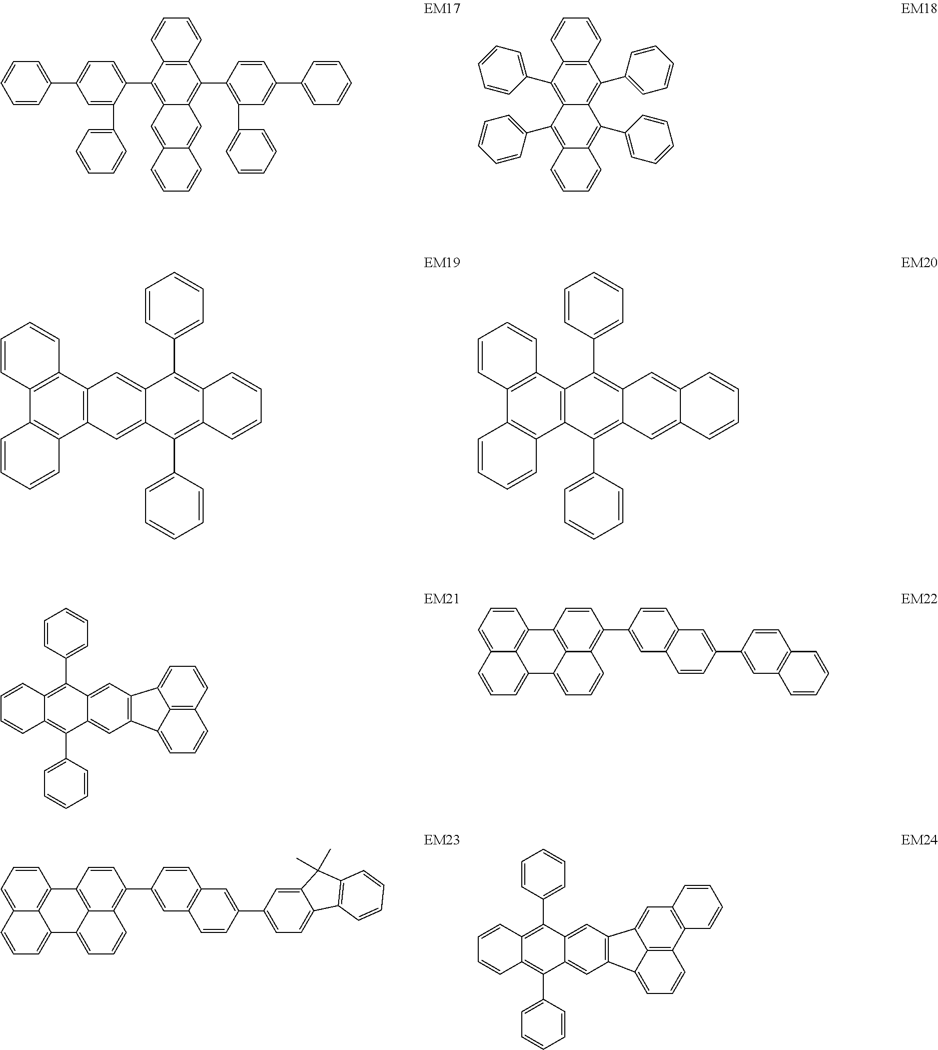

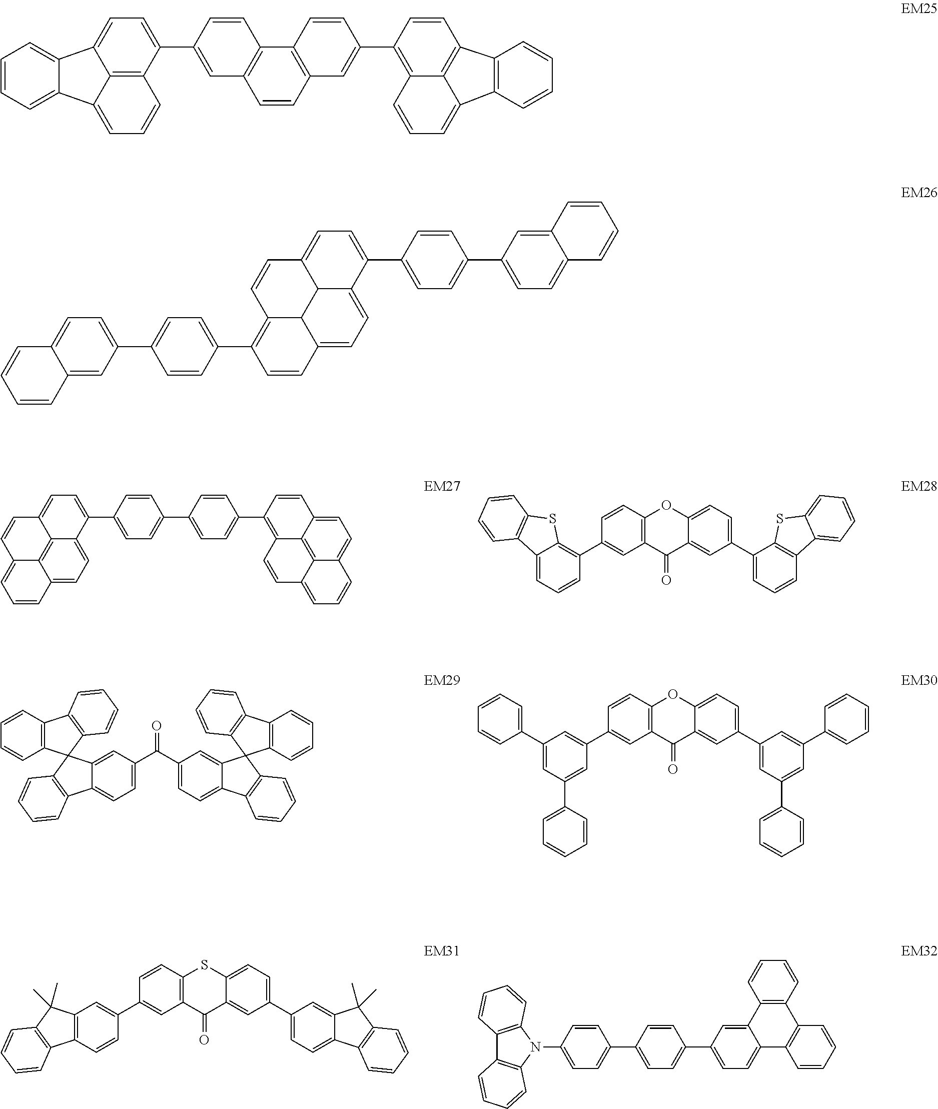

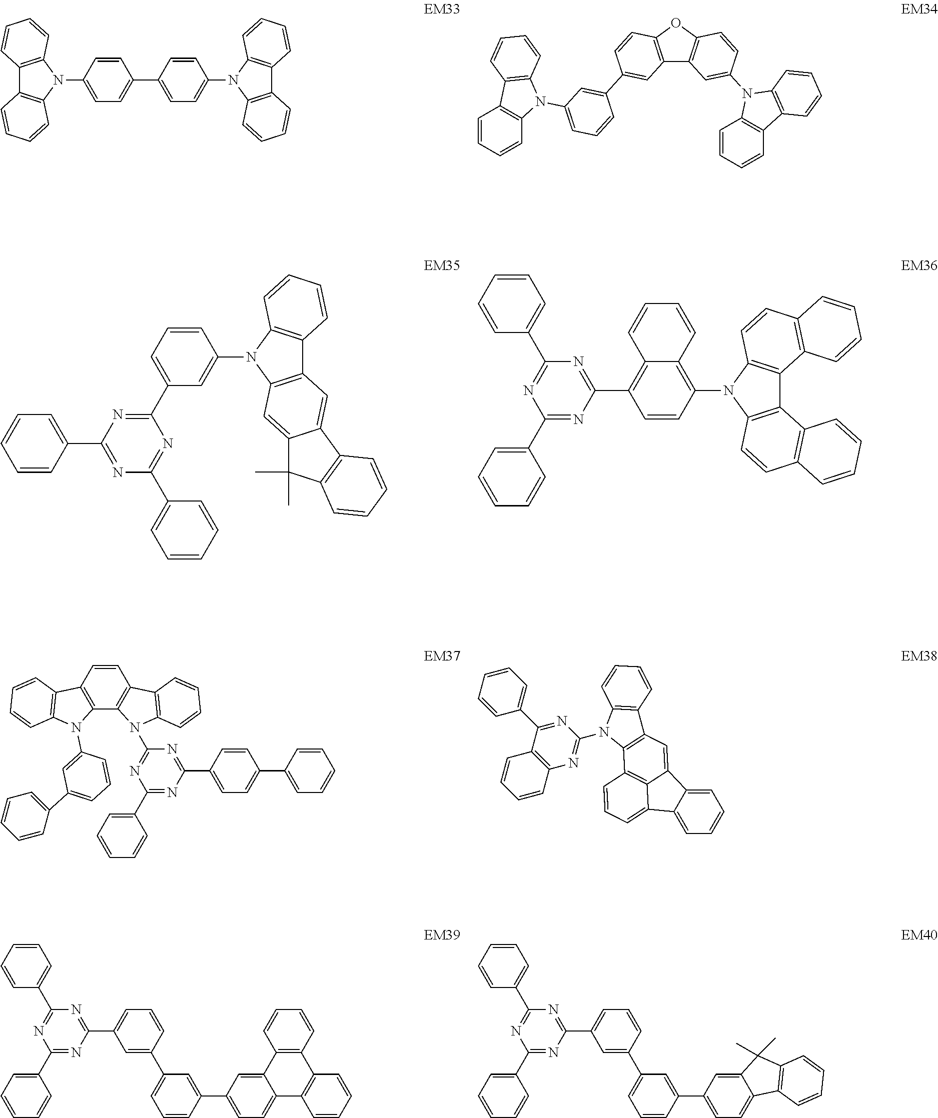

Specific examples RD1 to RD10 of the red light emitting dopant material are as described below. The dope concentration of the red light emitting dopant material is preferably 0.1% by mass or more and less than 5% by mass, and more preferably 0.1% by mass or more and less than 0.5% by mass. The concentration being excessively low unfavorably causes reduction in red light emitting intensity. Conversely, the concentration being excessively high unfavorably causes concentration quenching.

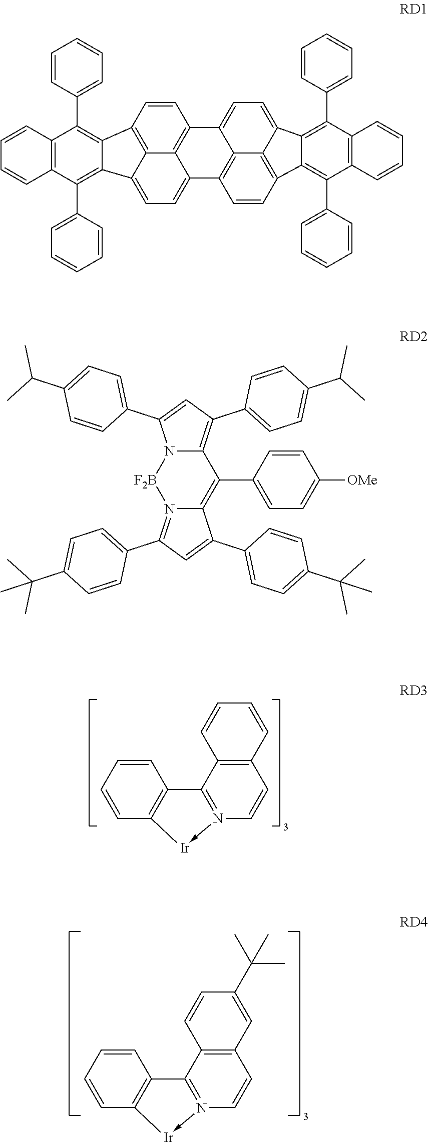

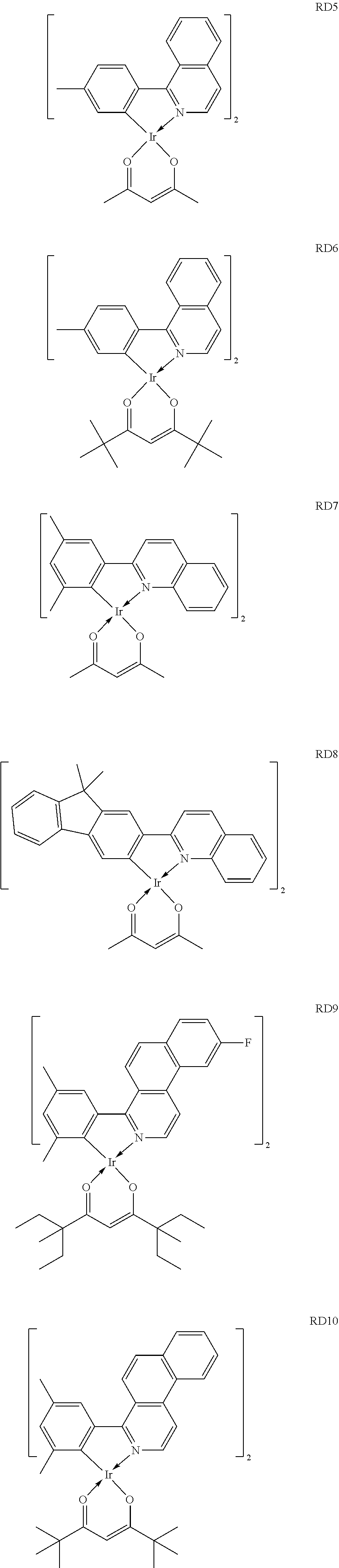

Specific examples GD1 to GD15 of the green light emitting dopant material are as described below. The dope concentration of the green light emitting dopant material is preferably 0.1% by mass or more and less than 10% by mass, and more preferably 1% by mass or more and less than 5% by mass.

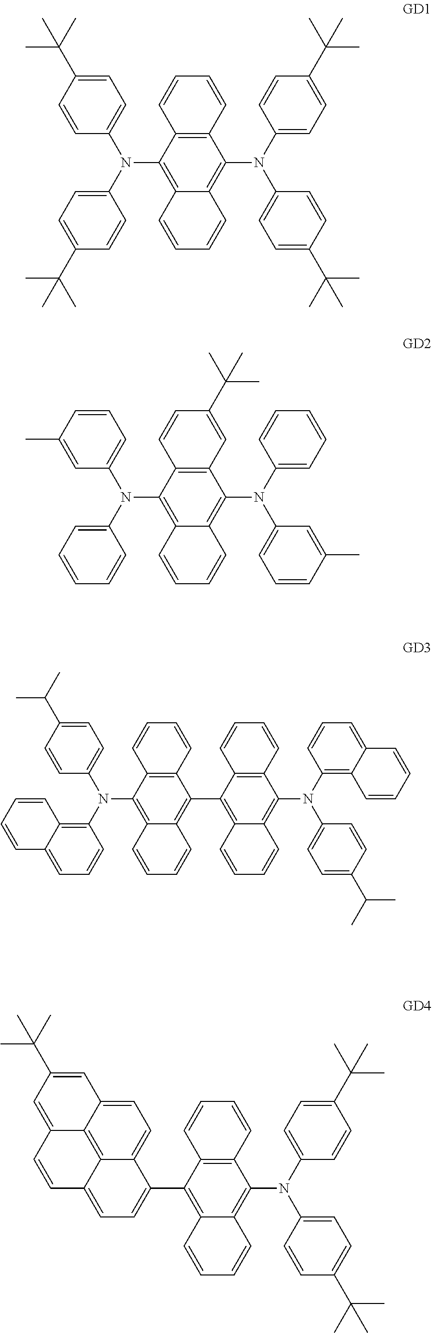

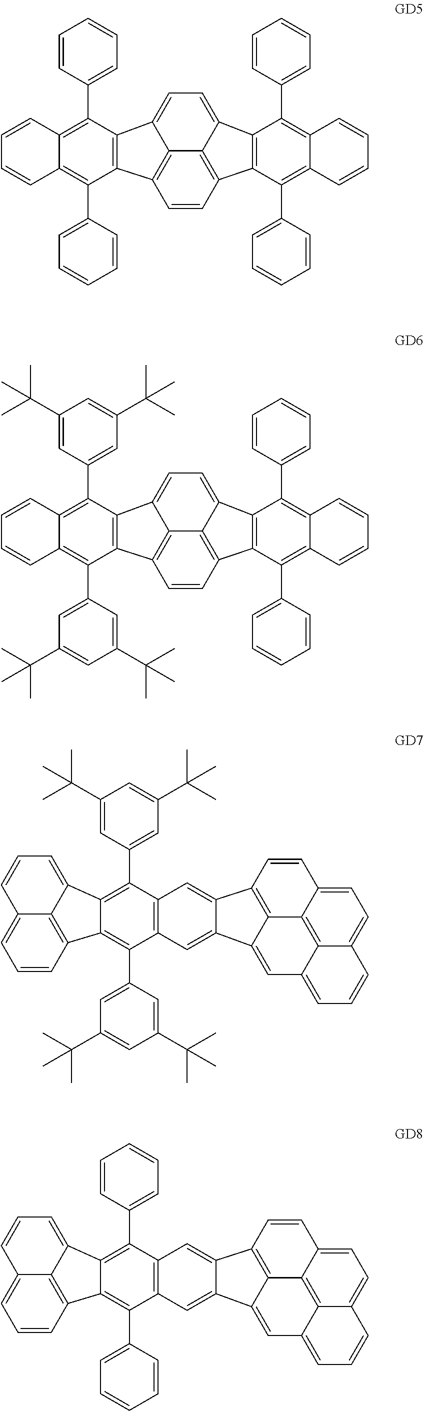

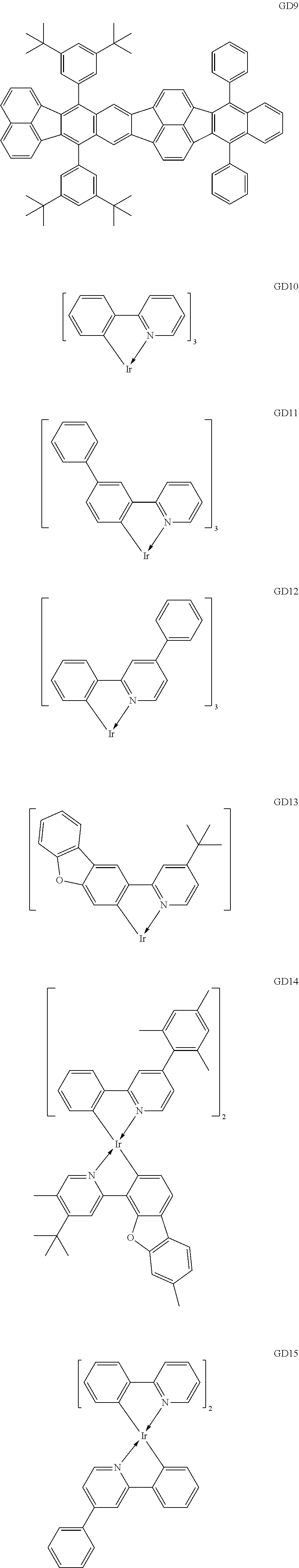

Specific examples BD1 to BD31 of the blue light emitting dopant material are as described below. The dope concentration of the blue light emitting dopant material is preferably 0.1% by mass or more and less than 5% by mass, and more preferably 0.3% by mass or more and less than 3% by mass.

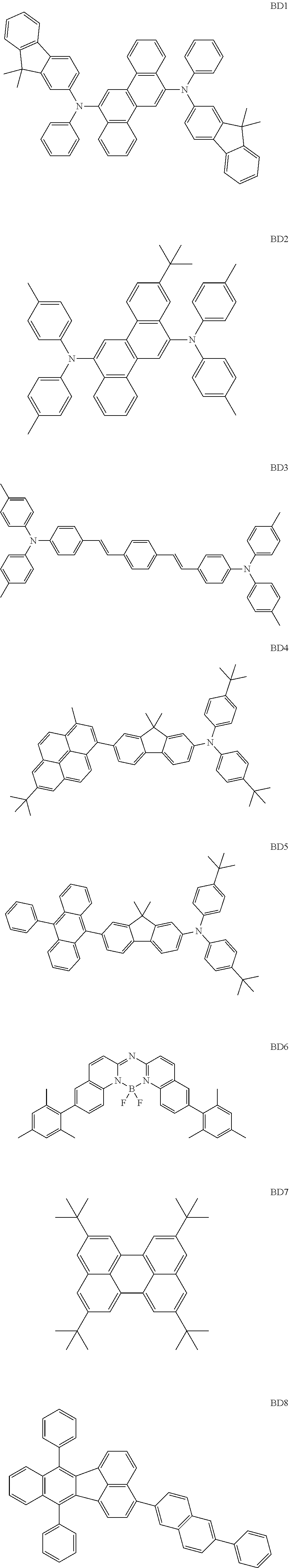

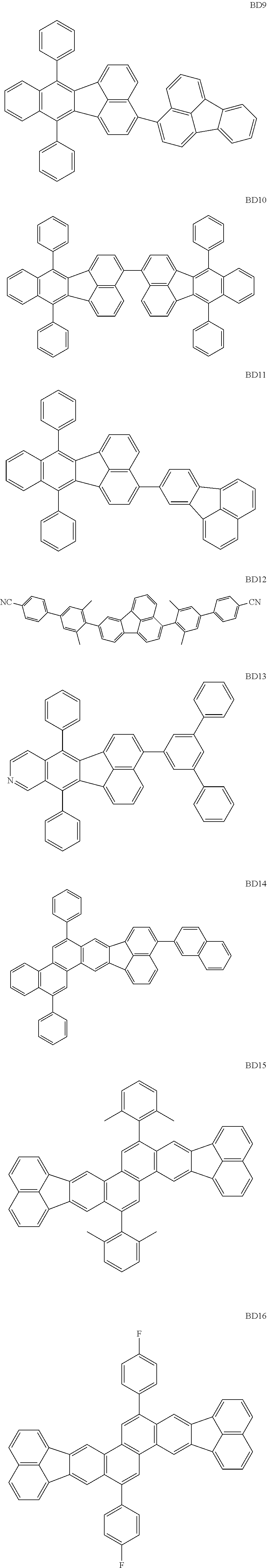

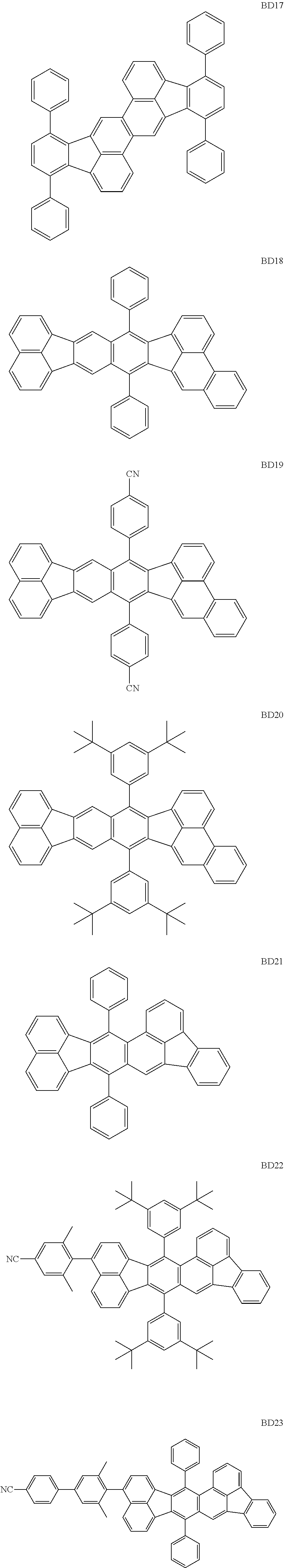

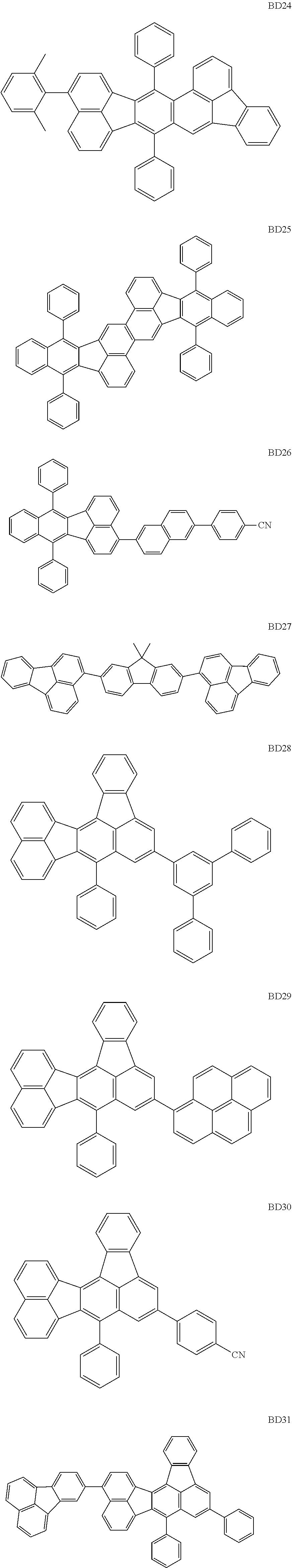

In the present disclosure, a plurality of light emitting dopants may be contained in or stacked on a host material so as to be used. The light emitting layers 13a and 13b may be the same or differ from each other in color.

Any material capable of transporting electrons to the light emitting layers 13a and 13b may be selected as the electron transport layers 14a and 14b, and is selected in consideration of, for example, the balance against the hole mobility of the hole transport material. Examples of the material that exerts electron transport performance include oxadiazole derivatives, oxazole derivatives, pyridine derivatives, pyrazine derivatives, triazole derivatives, triazine derivatives, quinoline derivatives, quinoxaline derivatives, phenanthroline derivatives, organic aluminum complexes, and condensed ring compounds (for example, fluorene derivatives, naphthalene derivatives, chrysene derivatives, anthracene derivatives, and fluoranthene derivatives). Specific examples ET1 to ET23 of the material used for forming the electron transport layers 14a and 14b are as described below, but the material is not limited to these.

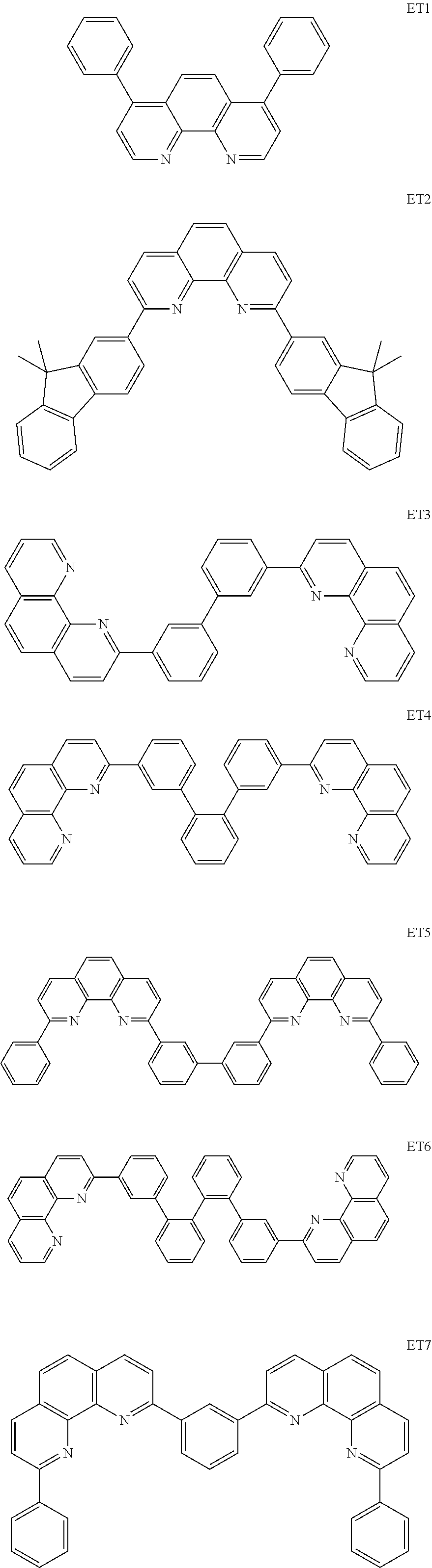

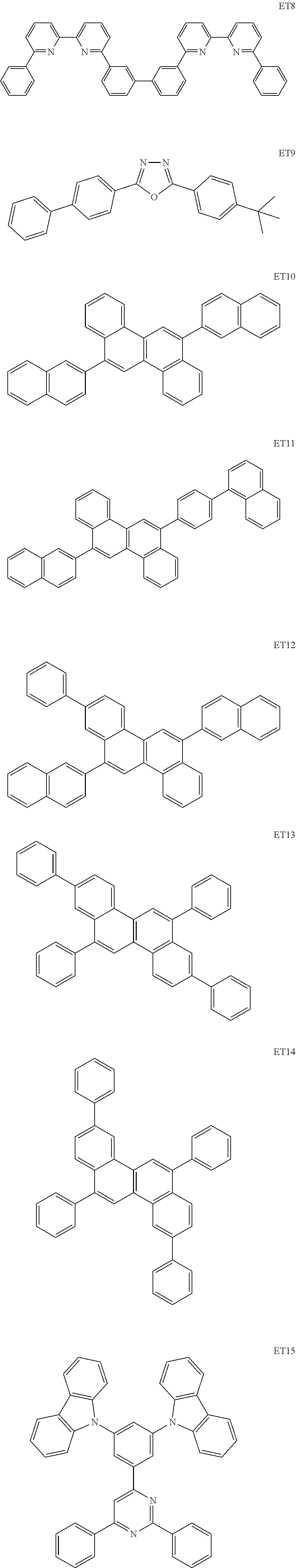

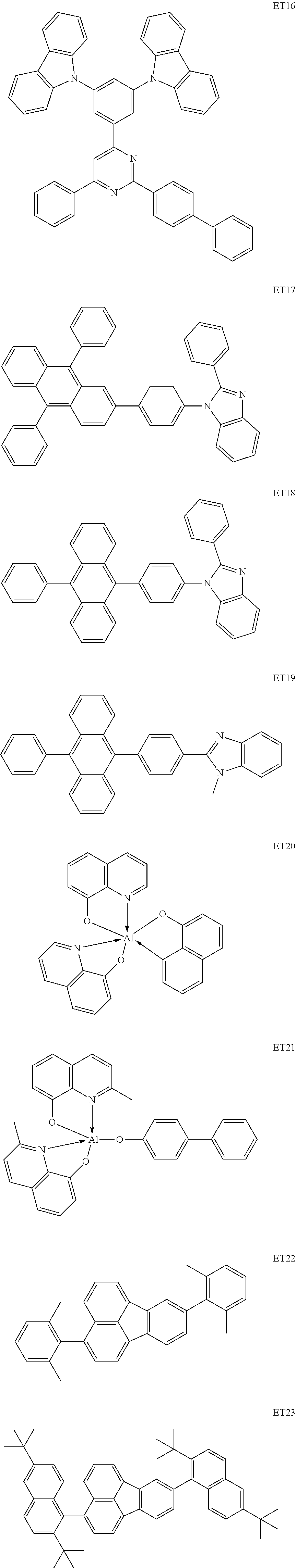

In the present disclosure, a hole block layer (not illustrated in the drawing) may be disposed between the light emitting layer 13a and the electron transport layer 14a and between the light emitting layer 13b and the electron transport layer 14b, and the above-described electron transport material is also favorably used for the hole block layer. In this regard, of the electron transport materials described as examples, the hole blocking material can be a compound composed of only hydrocarbon from the viewpoint of the bonding stability. The electron transport layers 14a and 14b can be composed of a material, such as ET1 to ET8 which have a pyridyl group or a phenanthryl group as a substituent. This is because an effect of reducing an electron injection barrier is exerted due to an interaction with the electron injection material such as the alkali metal compound or the electrode material.

In the present disclosure, the organic EL layer 10b nearer to the negative electrode 5 may include the electron injection layer 15b nearer than the light emitting layer 13b to the negative electrode 5. In this regard, the alkali metal compound such as LiF or Cs₂CO₃ used for the intermediate layer 20 can be used for the electron injection layer 15b, and the alkali metal compound is reduced during vapor deposition of the negative electrode 5 so as to exert the electron injection performance.

The negative electrode 5 can have a small work function. However, the alkali metal such as Li is unfavorably unstable in air, and the metal of group II such as Ca or Mg, a mixture in which Al, titanium (Ti), manganese (Mn), Ag, Lead (Pb), chromium (Cr), or the like is mixed in the metal of group II, and an alloy may also be used. For example, Mg—Ag, Mg—Al, and the like may be used. In addition, metal oxides such as ITO may be exploited. One of these electrode materials may be used alone, or at least two types may be used in combination. In this regard, the negative electrode 5 may have a single layer configuration or a multilayer configuration.

The negative electrode 5 can be a top emission element by using a thin film of Ag or a Ag alloy or an oxide conductive layer of ITO or the like.

There is no particular limitation regarding the method for forming the negative electrode 5, and a direct current sputtering method, an alternating current sputtering method, and a vapor deposition method are mentioned.

After the negative electrode 5 is formed, a sealing member not illustrated in the drawing may be formed. For example, glass provided with a moisture absorbent being bonded to the negative electrode 5 enables water and the like to be suppressed from entering the organic EL layers 10a and 10b and enables defective display to be suppressed from occurring. Alternatively, water and the like may be suppressed from entering the organic EL layers 10a and 10b by forming a passivation film of aluminum oxide, silicon nitride, or the like on the negative electrode 5. For example, the negative electrode 5 after being formed may be transported to another chamber without breaking the vacuum, and a sealing film may be formed by forming a silicon nitride film having a thickness of 2 μm through a CVD method.

Each pixel may be provided with a color filter. For example, a color filter adjusted to the pixel size may be formed on another substrate and may be bonded to a substrate provided with the organic EL element, or a color filter may be patterned on a sealing film of silicon nitride or the like by using photolithography.

Of the layers included in the organic compound layer 4 constituting the organic EL element 1 according to the present disclosure, the layers other than the intermediate layer 20 are formed by using the method described below. Forming may be performed by a dry process, for example, a vacuum vapor deposition method, an ionization vapor deposition method, sputtering, and plasma. In this regard, a wet process in which a layer is formed by performing dissolution in an appropriate solvent and by using a known coating method (for example, spin coating, dipping, a casting method, an LB method, and an ink jet method) may be used instead of the dry process. When a layer is formed by using a vacuum vapor deposition method, a solution coating method, or the like, crystallization and the like does not readily occur, excellent stability over time is exerted. When a layer is formed by using a coating method, the film may be formed in combination with an appropriate binder resin. The intermediate layer 20 can be formed through vapor deposition since a reduced form of the alkali metal is contained. The method is not limited to vapor deposition provided that a method other than vapor deposition is capable of forming the intermediate layer 20 while the alkali metal is in a reduced form.

Examples of the binder resin include polyvinylcarbazole resins, polycarbonate resins, polyester resins, ABS resins, acrylic resins, polyimide resins, phenol resins, epoxy resins, silicon resins, and urea resins, but the binder resin is not limited to these.

In this regard, one of the binder resins may be used alone as a homopolymer or a copolymer, or at least two types may be used in combination. Further, as the situation demands, known additives, such as plasticizers, oxidation inhibitors, and ultraviolet absorbents, may be used in combination.

### Apparatus Including Organic EL Element

The organic EL element according to the present disclosure may be used as the constituent material of display apparatuses, illumination apparatuses, and the like. In addition, examples of the application include exposure light sources of electrophotographic image forming apparatuses, backlights of liquid crystal display apparatuses, and light emitting apparatuses including a white light source and a color filter.

The display apparatus may be an image information processing apparatus including an image input portion which inputs image information from an area CCD, a linear CCD, a memory card, or the like, including an information processing portion which processes the input information, and displaying the input image on a display portion.

The display portions included in an imaging apparatus or an ink jet printer may have a touch panel function. There is no particular limitation regarding the driving system of the touch panel function, and the system may be any one of an infrared system, a capacitance system, a resistance film system, and an electromagnetic induction system. In addition, the display apparatus may be used as a display portion of a multifunction printer.

Various equipment and apparatuses which include the organic EL element according to the present disclosure will be described below with reference to the embodiments.

### Image Forming Apparatus

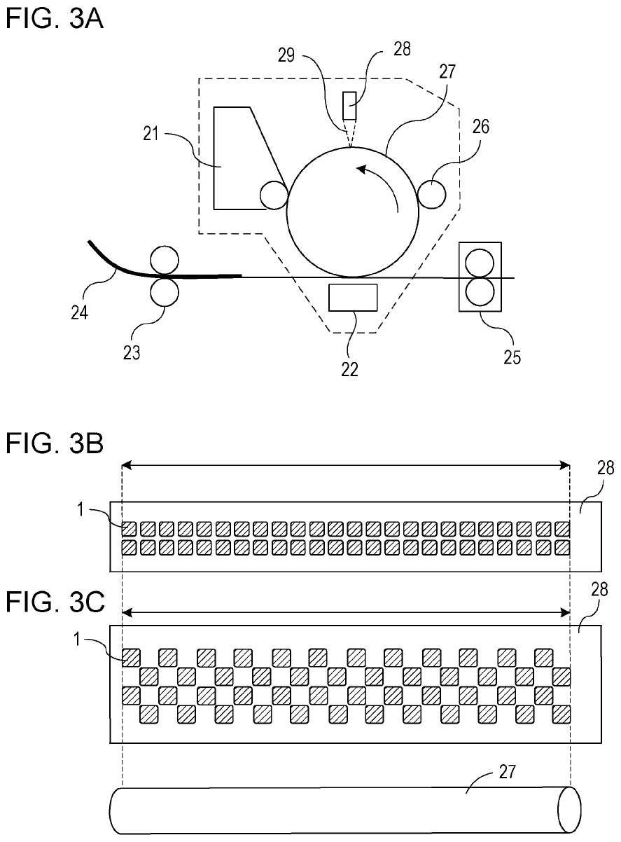

FIG. 3A is a schematic diagram illustrating the configuration of an embodiment of an image forming apparatus including an exposure apparatus according to the present disclosure. The image forming apparatus according to the present embodiment is an electrophotographic image forming apparatus including a photosensitive member 27, an exposure light source 28, a developing portion 21, a charge portion 26, a transfer unit 22, a transporting portion 23, and a fixing portion 25.

Light 29 is applied from the exposure light source 28, and an electrostatic latent image is formed on the surface of the photosensitive member 27. The exposure light source 28 includes the organic EL element according to the present disclosure. The developing portion 21 includes a toner and the like, and the charge portion 26 charges the photosensitive member 27. The transfer unit 22 transfers the developed image to a recording medium 24 such as paper, and the transporting portion 23 transports the recording medium 24. The fixing portion 25 fixes the image formed on the recording medium 24.

FIG. 3B and FIG. 3C are schematic diagrams illustrating the configuration of the exposure light source 28 in which a plurality of organic EL elements 1 according to the present disclosure serving as a light emitting portion are arranged on an elongated substrate. An arrow illustrated in the drawing indicates the direction parallel to the shaft of the photosensitive member 27 and the line direction of the arranged organic EL elements 1. The line direction is the same as the direction of the rotating shaft of the photosensitive member 27 and may be also referred to as the major axis direction of the photosensitive member 27.

FIG. 3B illustrates a form in which the organic EL elements 1 are arranged in the major axis direction of the photosensitive member. FIG. 3C illustrates a form different from 3B and illustrates a form in which the organic EL elements 1 in the first line and the second line are in a staggered arrangement in the line direction. The positions of the organic EL elements 1 in the first line differ, in the row direction, from the positions of the organic EL elements 1 in the second line. In the first line, the plurality of organic EL elements 1 are arranged at a predetermined spacing. In the second line, the organic EL elements 1 are located at the positions corresponding to the space between the organic EL elements 1 in the first line. That is, the plurality of organic EL elements 1 are arranged at a predetermined spacing in the row direction.

The arrangement illustrated in FIG. 3C translates into, for example, a state in which the organic EL elements 1 are arranged in a lattice pattern, a state in which the organic EL elements 1 are arranged in a hound's-tooth check pattern, or a checkered pattern.

### Display Apparatus

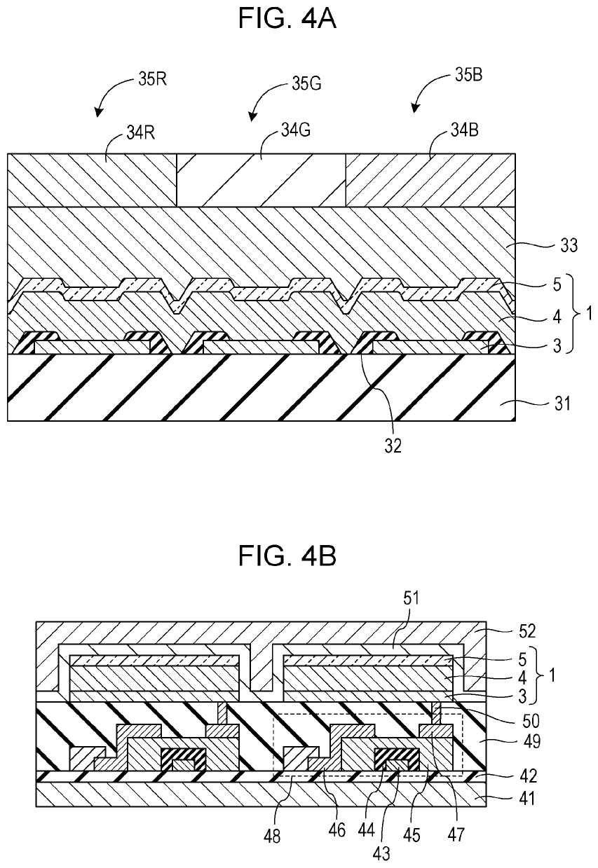

FIGS. 4A and 4B are schematic sectional views in the thickness direction illustrating an embodiment of the display apparatus according to the present disclosure. The display apparatus according to the present disclosure includes a plurality of pixels, and at least one of the plurality of pixels is the organic EL element according to the present disclosure.

FIG. 4A is a schematic sectional view illustrating the configuration of a pixel of an embodiment of the display apparatus including the organic EL element according to the present disclosure. In the present embodiment, a pixel has three subpixels 35 divided into 35R (red light emission), 35G (green light emission), and 35B (blue light emission) in accordance with the light emission. In the present embodiment, the organic EL element 1 emits white light, and the white light emitted from the organic EL element 1 is passed through color filters 34R (red), 34G (green), and 34B (blue) so as to obtain respective light emission colors. The subpixels 35R, 35G, and 35B include an organic EL element 1 on an interlayer insulating layer 31 serving as a substrate. In the present embodiment, the positive electrode 3 is formed on a subpixel 35 basis, and individual positive electrodes 3 are electrically insulated from each other by the respective insulating layers 32.

In the present embodiment, since the light is emitted from the side provided with the color filters 34R, 34G, and 34B, the negative electrode 5 is a transparent electrode, and the positive electrode 3 is a reflection electrode. The organic compound layer 4 and the negative electrode 5 are common to the plurality of pixels. Any one of the positive electrode 3 and the negative electrode 5 of the organic EL element 1 may be arranged nearer to the interlayer insulating layer 31. When the electron injection layer included in the organic compound layer 4 is formed of an alkali metal compound, to reduce the alkali metal compound, the positive electrode 3 may be formed nearer to the interlayer insulating layer 31, and the layers may be formed from the positive electrode 3 toward the negative electrode 5 successively.

In FIG. 4A, reference 33 denotes a protective layer. The insulating layer 32 is also referred to as a bank or pixel isolation layer, and a region not covered with the insulating layer 32 of the positive electrode 3 is in contact with the organic compound layer 4 and serves as a light emitting region.

The protective layer 33 suppresses water from entering the organic compound layer 4. The protective layer 33 may be a single layer or a plurality of layers. In the instance of the plurality of layers, each layer may be an inorganic compound layer or an organic compound layer.

The color filters 34R, 34G, and 34B may be formed on a planarizing film not illustrated in the drawing.

In this regard, a resin protective layer not illustrated in the drawing may be formed on the color filters 34R, 34G, and 34B.

The color filters 34R, 34G, and 34B may be formed on an opposing substrate such as a glass substrate and, thereafter, be bonded.

The size of the light emitting region surrounded by the insulating layer 32 is preferably 5 μm or more and 15 μm or less, and more specifically, the size may be 11 μm, 9.5 μm, 7.4 μm, 6.4 μm, or the like. The spacing between subpixels may be 10 μm or less, and more specifically, the spacing may be 8 μm, 7.4 μm, or 6.4 μm.

The pixels may have a known arrangement pattern in plan view. For example, a stripe arrangement, a delta arrangement, a pentile arrangement, or a Bayer arrangement may be adopted. The form of the subpixel in plan view may be any known form. Examples include a quadrangle, such as a rectangle and a rhombus, and a hexagon. As a matter of course, the form is not limited to being an accurate figure and nearly rectangular forms are included in the rectangle.

The form of the subpixel and the pixel array may be adopted in combination.

FIG. 4B is a schematic sectional view illustrating the configuration of a pixel of another embodiment of the display apparatus including the organic EL element according to the present disclosure. In the present embodiment, a transistor 48 is connected to the organic EL element 1. The transistor 48 illustrated in FIG. 4B is a thin film transistor (TFT) but may be a transistor other than TFT or an active element other than the transistor.

In the present embodiment, a substrate 41 of glass, silicon, or the like and an insulating layer 42 disposed thereon are included, and the transistor 48 is arranged on the insulating layer 42. The transistor 48 is composed of a gate electrode 43, a gate insulating layer 44, a semiconductor layer 45, a drain electrode 46, and a source electrode 47. An insulating layer 49 is disposed on the transistor 48, and a positive electrode 3 of the organic EL element 1 is connected to a source electrode 47 of the transistor 48 through a contact hole 50 formed in the insulating layer 49.

In this regard, the method of electrical connection between the electrodes (positive electrode 3 and negative electrode 5) included in the organic EL element 1 and the electrodes (source electrode 47 and drain electrode 46) included in the transistor 48 is not limited to the form illustrated in FIG. 4B. That is, any one of the positive electrode 3 and the negative electrode 5 has to be electrically connected to any one of the source electrode 47 and the drain electrode 46 of TFT. Any one of the positive electrode 3 and the negative electrode 5 of the organic EL element 1 may be arranged nearer to the transistor 48. When the electron injection layer included in the organic compound layer 4 is formed of an alkali metal compound, to reduce the alkali metal compound, the positive electrode 3 may be formed nearer to the substrate 41, and the layers may be formed successively from the positive electrode 3 toward the negative electrode 5.

In FIG. 4B, references 51 and 52 denote protective layers to suppress the organic EL element 1 from deteriorating.

The transistor 48 is not limited to being TFT including an active layer (semiconductor layer 45) on the insulating surface of the substrate 41 and may be a transistor including single-crystal silicon wafer. Examples of the active layer include single-crystal silicon, non-single-crystal silicon, such as amorphous silicon and microcrystalline silicon, and non-single-crystal oxide semiconductors, such as indium zinc oxide and indium gallium zinc oxide. Therefore, in the present embodiment, the transistor 48 may also be formed in the substrate 41 such as a Si substrate. In this regard, being formed in the substrate 41 denotes the transistor being produced by working just the substrate 41 such as a Si substrate. That is, the transistor being included in the substrate 41 may appear that the substrate 41 and the transistor 48 are integrally formed. Whether the transistor is included in the substrate 41 or TFT is used on the substrate 41 is selected in accordance with the size of the display portion. For example, when the size is about 0.5 inches, the organic EL element 1 can be disposed on the Si substrate.

The emission illuminance of the organic EL element 1 according to the present embodiment is controlled by the transistor 48 which is an example of the switching element, and a plurality of organic EL elements 1 being disposed in a plane enables the image to be displayed with the respective emission illuminance.

In the present embodiment, the organic EL element 1 may be incorporated in a pixel circuit. The pixel circuit may be an active matrix type that independently control the light emission of the organic EL element 1. The active matrix type circuit may be voltage programming or current programming. A driving circuit has a pixel circuit on a pixel basis. The pixel circuit may have a transistor to control the emission illuminance of the organic EL element 1, a transistor to control the light emission timing, capacitance to maintain the gate voltage of the transistor to control the emission illuminance, and a transistor to connect to GND without through the organic EL element 1.

The display apparatus have a display region and a peripheral region disposed in the periphery of the display region. The display region includes a pixel circuit, and the peripheral region includes a display control circuit. The mobility of the transistor constituting the pixel circuit may be smaller than the mobility of the transistor constituting the display control circuit.

The gradient of the current-voltage characteristics of the transistor constituting the pixel circuit may be smaller than the gradient of the current-voltage characteristics of the transistor constituting the display control circuit. The gradient of the current-voltage characteristics may be measured on the basis of the so-called Vg-Ig characteristics.

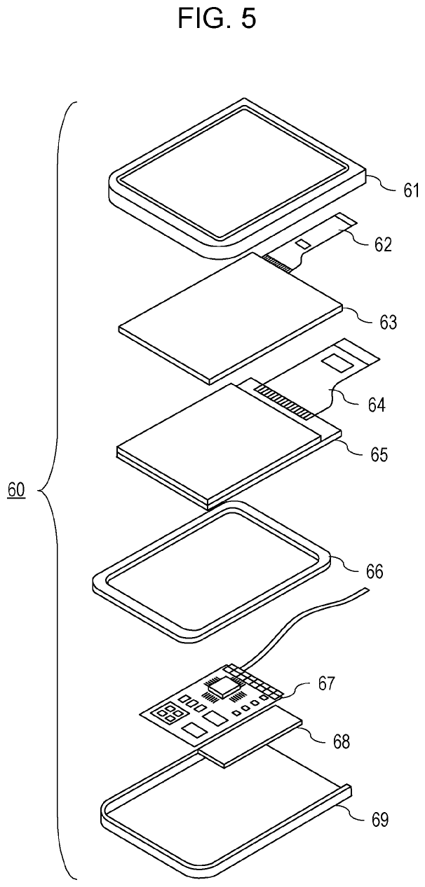

FIG. 5 is an exploded perspective view illustrating the entire configuration of an embodiment of the display apparatus according to the present disclosure. A display apparatus 60 includes a touch panel 63, a display panel 65, a frame 66, a circuit board 67, and a battery 68 between an upper cover 61 and a lower cover 69. The touch panel 63 and the display panel 65 are connected to flexible print circuits (FPC) 62 and 64, respectively. The circuit board 67 is printed with a transistor. The battery 68 is not limited to being disposed unless the display apparatus is portable equipment and may be disposed at another position even when the display apparatus is portable equipment.

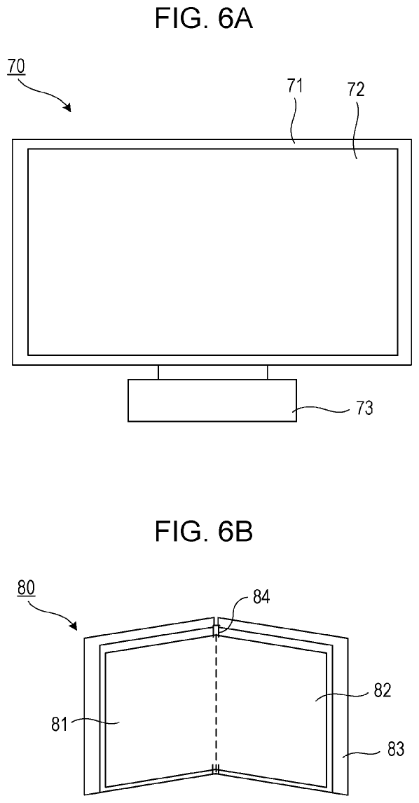

FIGS. 6A and 6B are schematic front views illustrating another embodiment of the display apparatus according to the present disclosure. FIG. 6A is a display apparatus of a television monitor, a PC monitor, and the like. The display apparatus 70 includes a frame 71 and a display portion 72. The organic EL element according to the present disclosure is used for the display portion 72.

In addition, the display apparatus 70 includes a foundation 73 to support the frame 71 and the display portion 72. The foundation 73 is not limited to the form illustrated in FIG. 6A, and the lower side of the frame 71 may also serve as the foundation. In this regard, the frame 71 and the display portion 72 may be curved, and the radius of curvature is preferably 5,000 mm or more and 6,000 mm or less.

A display apparatus 80 illustrated in FIG. 6B is a so-called foldable display apparatus configured to be capable of being folded. The display apparatus 80 includes a first display portion 81, a second display portion 82, a casing 83, and a folding point 84. The first display portion 81 and the second display portion 82 are formed by using the organic EL element according to the present disclosure. The first display portion 81 and the second display portion 82 may form a seamless display apparatus. The first display portion 81 and the second display portion 82 is divided at the folding point 84. The first display portion 81 and the second display portion 82 may display images that differ from each other, or the first display portion 81 and the second display portion 82 may display an image in combination.

### Imaging Apparatus

The organic EL element according to the present disclosure is used for the display portion of an imaging apparatus including an optical portion having a plurality of lenses and an imaging element to receive the light passed through the optical portion. The imaging apparatus includes the display portion to display information acquired by the imaging element. In this regard, the display portion may be a display portion exposed to the outside of the imaging apparatus or a display portion arranged inside a finder. Examples of the imaging apparatus include digital cameras and digital camcorders.

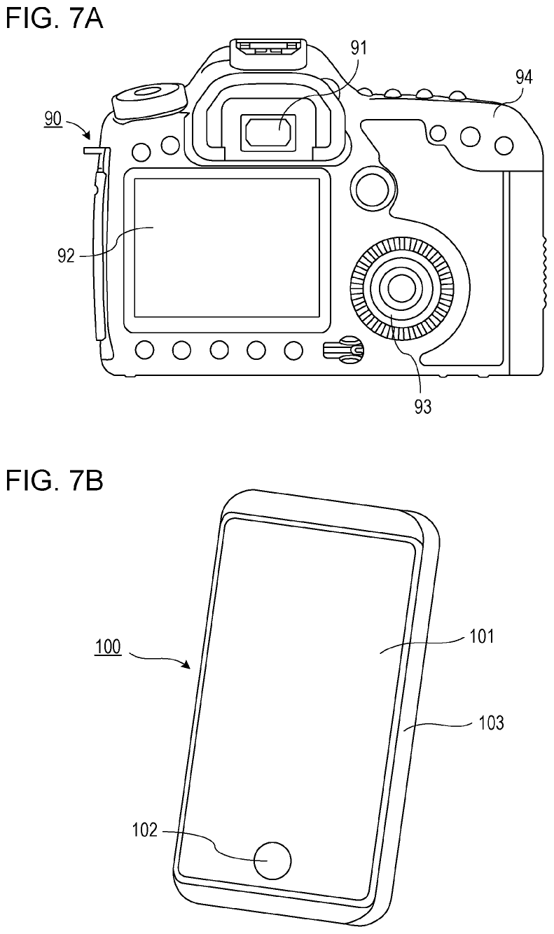

FIG. 7A is a schematic front view illustrating an embodiment of the imaging apparatus according to the present disclosure. The imaging apparatus 90 according to the present embodiment includes a view finder 91, a rear plane display 92, an operation portion 93, and a casing 94, and the view finder 91 is the display portion including the organic EL element according to the present disclosure. The view finger 91 may display not only an image to be imaged but also environmental information, imaging instructions, and the like. The environmental information may include the intensity of the external light, the direction of the external light, the speed of movement of an object, the possibility of the object being shielded by a shielding material, and the like.

Since the timing suitable for imaging is a short time, it is desirable that the information be displayed as soon as possible. Since the organic EL element has a high response speed, using the organic EL element according to the present disclosure realizes quick display and is favorably adopted compared with a liquid crystal display apparatus when a high display speed is desirable.

The imaging apparatus 90 includes an optical portion not illustrated in the drawing. The optical portion has a plurality of lenses, and an image is formed on the imaging element housed in the casing 94. The relative positions of the plurality of lenses being adjusted enables the focal point to be adjusted. This operation may also be automatically performed. The imaging apparatus may be referred to as a photoelectric conversion apparatus. The imaging method of the photoelectric conversion apparatus may include a method in which a difference from the last image is detected, a method in which an image is cut from a consistently recorded image, and the like instead of successive imaging.

### Electronic Equipment

The organic EL element according to the present disclosure may be used for the display portion of a portable terminal. In such an instance, both a display function and an operation function may be provided. Examples of the portable terminal include mobile phones such as smart phones, tablets, and head-mounted displays.

FIG. 7B is a schematic perspective view illustrating an embodiment of the electronic equipment according to the present disclosure. The electronic equipment 100 includes a display portion 101, an operation portion 102, and a casing 103. The casing 103 includes a circuit, a printed circuit board provided with the circuit, a battery, and a communications portion, and the operation portion 102 may be a button or a touch panel type reaction portion. The operation portion 102 may be a biometric authentication portion to, for example, release the lock based on fingerprint authentication. The electronic equipment including a communications portion is also referred to as communications equipment. The electronic equipment may further have a camera function by being provided with a lens and an imaging element. An image imaged by using the camera function is reflected on the display portion. Examples of the electronic equipment include smart phones and notebook personal computers.

### Illumination Apparatus

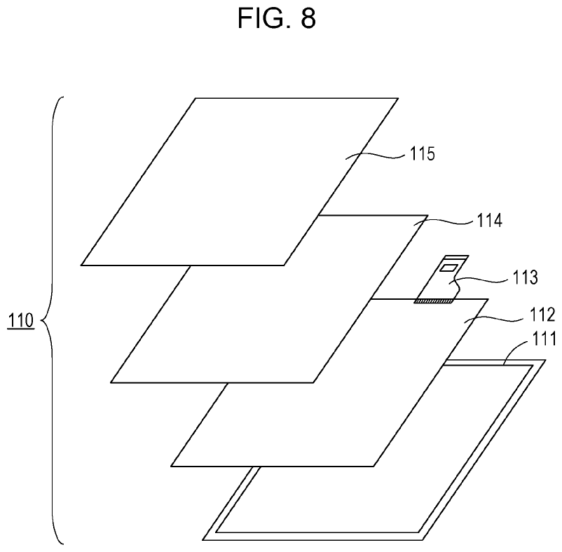

FIG. 8 is an exploded perspective view illustrating an embodiment of an illumination apparatus according to the present disclosure. An illumination apparatus 110 according to the present embodiment includes a casing 111, a light source 112, a circuit board 113, an optical filter 114 to pass through the light from the light source 112, and a light diffusion portion 115. The light source 112 is formed by using the organic EL element according to the present disclosure and a power supply circuit connected to the organic EL element. The power supply circuit is a circuit to convert the alternating current voltage to the direct current voltage. The optical filter 114 may be a filter to improve the color rendering of the light source 112. The light diffusion portion 115 enables the light of the light source 112 to be effectively diffused and enables the light to reach over a wide range so as to illuminate, for example. The optical filter 114 and the light diffusion portion 115 are disposed on the light emission side of the illumination. As the situation demands, a cover may be disposed on the outermost portion.

The illumination apparatus 110 is, for example, an apparatus to illuminate the interior. The illumination apparatus 110 may emit white color, neutral white color, and any one of blue to red color and may have a light modulating circuit to modulate the light. The white has a color temperature of 4,200 K, and the neutral white has a color temperature of 5,000 K. The illumination apparatus 110 may include a color filter.

The illumination apparatus 110 may include a heat dissipation portion. The heat dissipation portion dissipates the heat of the interior of the apparatus to the outside of the apparatus, and a metal having high specific heat, liquid silicon, or the like is adopted. Mobile unit

The mobile unit according to the present disclosure may be a ship, an aircraft, a drone, or the like. The mobile unit includes a bodywork and a lighting appliance attached to the bodywork, and the lighting appliance includes the organic EL element according to the present disclosure and has a responsibility for light emission to notify the position of the bodywork.

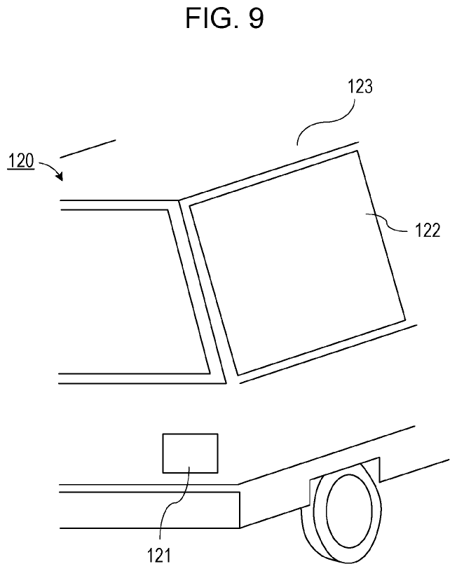

FIG. 9 is a schematic perspective view illustrating an automobile which is an embodiment of the mobile unit according to the present disclosure. The automobile 120 according to the present embodiment includes a tail lamp 121 serving as a lighting appliance, and the tail lamp 121 is lit when a braking operation and the like are performed. The automobile 120 includes a car body 123 and a window 122 attached to the car body 123. In the present embodiment, at least one of the tail lamp 121 and the window 122 includes the organic EL element according to the present disclosure.

In this regard, the tail lamp 121 may include a protective member to protect the organic EL element.

There is no particular limitation regarding the material for forming the protective member provided that the protective member has somewhat high strength and is transparent, and the protective member is favorably composed of a polycarbonate or the like. Polycarbonate may be mixed with a furandicarboxylic acid derivative, an acrylonitrile derivative, or the like.

The window 122 may be a transparent display unless the window is a window to check the front and rear of the automobile. When the transparent display includes the organic EL element according to the present disclosure, the constituent materials of the electrode and the like included in the organic EL element are composed of transparent members.

### Imaging Display Apparatus

The imaging display apparatus including the organic EL element according to the present disclosure may be applied to systems capable of being equipped as wearable devices such as glasses (smart glasses), HMD, and smart contacts. The imaging display apparatus used for such application examples includes an imaging apparatus capable of performing photoelectric conversion of the visible light and a display apparatus capable of emitting the visible light.

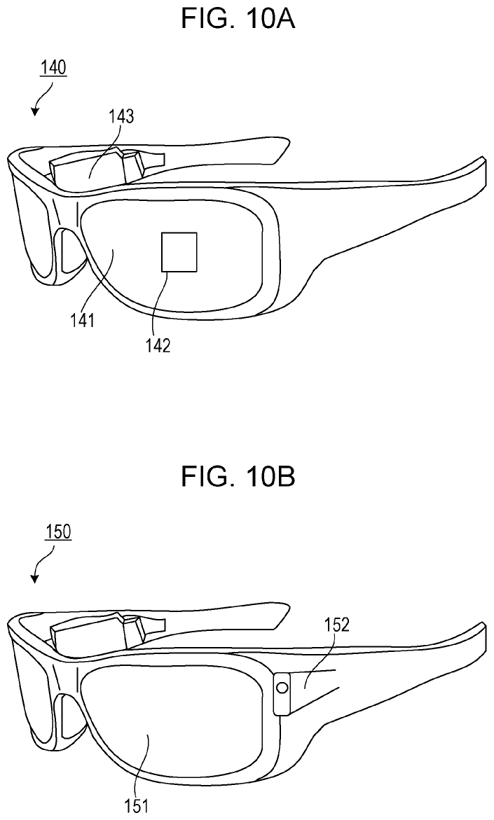

FIG. 10A illustrates glasses 140 which are an example of the application examples of the imaging display apparatus. An imaging apparatus 142 such as a CMOS sensor or SPAD is disposed on the surface side of the lens 141 of the glasses 140. In addition, a display apparatus (not illustrated in the drawing) including the organic EL element according to the present disclosure is disposed on the back surface side of the lens 141.

The glasses 140 further include a control apparatus 143. The control apparatus 143 functions as a power supply to supply electric power to the imaging apparatus 142 and the display apparatus according to each embodiment. In this regard, the control apparatus 143 controls the operations of the imaging apparatus 142 and the display apparatus. A lens 141 is provided with an optical system to concentrate the light on the imaging apparatus 142.

FIG. 10B also illustrates glasses, but the configuration is slightly different from FIG. 10A. The glasses 150 in FIG. 10B include a control apparatus 152, and an imaging apparatus corresponding to the imaging apparatus 142 in FIG. 10A and a display apparatus including the organic EL element according to the present disclosure are mounted on the control apparatus 152. A lens 151 is provided with the imaging apparatus in the control apparatus 152 and an optical system to project the light emitted from the display apparatus, and an image is projected on the lens 151. The control apparatus 152 functions as a power supply to supply electric power to the imaging apparatus and the display apparatus and also controls the operations of the imaging apparatus and the display apparatus. The control apparatus 152 may include a line-of-sight detection portion to detect the line of sight of a user wearing the glasses. Infrared rays may be used for detecting the line of sight. An infrared light emitting portion emits infrared rays to an eyeball of the user gazing at the display image. The image of the imaged eyeball is obtained by the imaging portion including a light receiving element detecting the emitted infrared rays reflected from the eyeball. A reducing device to reduce the light from the infrared light emitting portion to the display portion in plan view being included suppresses the image quality from deteriorating.

The line of sight of the user toward the display image is detected from the image of the imaged eyeball obtained by imaging the infrared rays. Any known method may be applied to the line-of-sight detection by using the image of the imaged eyeball. As an example, a line-of-sight detection method based on a Purkinje image due to reflection of irradiation light at the cornea may be used.

More specifically, line-of-sight detection treatment based on a pupil center corneal reflection method is performed. The pupil center corneal reflection method is used, and a line-of-sight vector indicating the direction (rotation angle) of the eyeball is calculated on the basis of the image of the pupil and the Purkinje image included in the image of the imaged eyeball so as to detect the line of sight of the user.

The imaging display apparatus according to the present embodiment may include the imaging apparatus including a light receiving element and may control a display image of the display apparatus on the basis of the line-of-sight information of the user from the imaging apparatus. Specifically, the display apparatus determines a first line-of-sight region at which the user gazes and a second line-of-sight region other than the first line-of-sight region on the basis of line-of-sight information. The first line-of-sight region and the second line-of-sight region may be determined by the control apparatus of the display apparatus, or a signal of determination by an external control apparatus may be received. In the display region of the display apparatus, the display resolution of the first line-of-sight region may be controlled so as to be higher than the display resolution of the second line-of-sight region. That is, the second line-of-sight region may have lower resolution than the first line-of-sight region.

The display region includes a first display region and a second display region different from the first display region. Of the first display region and the second display region, a region having a high priority is determined on the basis of the line-of-sight information. The first line-of-sight region and the second line-of-sight region may be determined by the control apparatus of the display apparatus, or a signal of determination by an external control apparatus may be received. The resolution of the high priority region may be controlled so as to be higher than the resolution of a region other than the high priority region. That is, the resolution of the region having a relatively low priority may be lowered.

In this regard, AI may be used for determining the first line-of-sight region and the high priority region. AI may be a model configured to estimate the angle of the line of sight and the line-of-sight distance up to the object on the basis of the image of the eyeball where the training data are the image of the eyeball and the actual line-of-sight direction of the eyeball of the image. The AI program may be included in any one of the display apparatus, the imaging apparatus, and the external apparatus. The AI program included in the external apparatus is passed to the display apparatus through communications.

Display control based on visual recognition detection can be applied to the smart glasses further including an imaging apparatus to image the outside. The smart glasses display imaged external information in real time.

### EXAMPLES

### Example 1

In the preset example, a top-emission type organic EL element in which each of the organic EL layers 10a and 10b included an electron block layer and a hole block layer in addition to the layer configuration illustrated in FIG. 2 was produced. Both the resulting first organic EL layer 10a and second organic EL layer 10b included a blue light emitting layer.

A Ti film of 40 nm serving as the positive electrode 3 was formed on a silicon substrate by using a sputtering method, and patterning was performed by using photolithography so as to form a regular hexagonal Ti pixel array with a pixel pitch of 4.2 μm and conductive lines. A silicon nitride (SiN) insulating layer was further formed on Ti, and patterning was performed by using photolithography so as to expose Ti at the pixel array and set the width of the SiN insulating layer delimiting the pixel array to be 1 μm.

Subsequently, the substrate on which the layers up to the insulating layer were formed and which was water-washed and materials were attached to a vacuum vapor deposition apparatus, evacuation to 1.0×10⁻⁴ Pa (1×10⁻⁶ Torr) was performed, and UV/ozone cleaning was performed.

Thereafter, layers up to the first organic EL layer 10a were formed, where the layer configuration is described in Table 1 below.

LiF and Mg were vapor co-deposited from a molybdenum vapor deposition boat at the respective vapor deposition rate of 0.1 Å/s so as to form an intermediate layer 20 having a volume ratio LiF:Mg of 50:50 and a thickness of 2 μm.

After the layers up to the second organic EL layer 10b and the negative electrode 5 were formed where the layer configuration is described in Table 1, the substrate was transferred to a glove box, and an organic EL layer was obtained by performing sealing with a glass cap including a desiccating agent in a nitrogen atmosphere.

TABLE 1

| | | | Film |
|---|---|---|---|
| | | | thickness |
| Layer | | Material | (nm) |
| Negative electrode 5 | | Mg + Ag | 10 |
| | | mass ratio = | |
| | | Mg:Ag = 50:50 | |
| Second | Electron injection layer 15b | LiF | 1 |
| organic EL | Electron transport layer 14b | ET2 | 20 |
| layer 10b | Hole block layer | ET12 | 20 |
| | Light emitting layer 13b | EM1 + BD9 | 10 |
| | | mass ratio = | |
| | | EM1:BD9 = | |
| | | 99.4:0.6 | |
| | Electron block layer | HT7 | 10 |
| | Hole transport layer 12b | HT2 | 18 |
| | Hole injection layer 11b | HT16 | 7 |
| Intermediate layer 20 | | LiF + Mg | 2000 |
| | | volume ratio = | |
| | | Li/Mg = 50/50 | |
| First | Electron injection layer 15a | LiF | 1 |
| organic EL | Electron transport layer 14a | ET2 | 20 |
| layer 10a | Hole block layer | ET12 | 20 |
| | Light emitting layer 13a | EM1 + BD9 | 10 |
| | | mass ratio = | |
| | | EM1:BD9 = | |
| | | 99.4:0.6 | |
| | Electron block layer | HT7 | 10 |
| | Hole transport layer 12a | HT2 | 18 |
| | Hole injection layer 11a | HT16 | 7 |

| | | |
|---|---|---|
| Positive electrode 3 | Ti | 40 |

Subsequently, a voltage applying apparatus was connected, and the characteristics were evaluated. When a voltage was applied to all pixels and the light emission state was examined by using a microscope, light emission on the insulating layer was not observed, and there was no variations in light emission. Therefore, the resulting organic EL element was favorable.

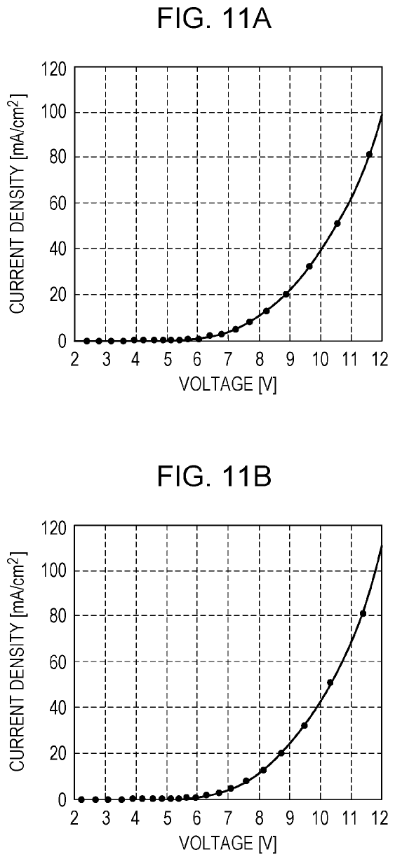

The voltage-current characteristics of the resulting organic EL element were measured by using a microammeter “4140B” produced by Hewlett-Packard Company, and the emission spectrum and the emission illuminance were acquired by using “SR-3” produced by TOPCON CORPORATION. The current efficiency determined by the energizing current value and the emission illuminance was 2.2 cd/A, the CIE chromaticity was x=0.14 and y=0.10. FIG. 11A illustrates the voltage-current characteristics. In this regard, for the purpose of comparison, an organic EL element in which the intermediate layer 20 and the second organic EL layer 10b were not included, and the organic EL layer was a single layer was produced, and the voltage-current characteristics were determined.

As a result, regarding the organic EL element according to the present embodiment, the voltage applied to the element to obtain the current density equal to the single-layer organic EL element was about 2.5 times the voltage for the single-layer organic EL element, and the current efficiency was about twice the current efficiency of the single-layer organic EL element. Therefore, it is conjectured that both the first organic EL layer 10a and the second organic EL layer 10b emitted light, and it can be said that the electron injection performance of the intermediate layer 20 was exerted and that the organic EL element was a layered type including the intermediate layer 20 having high resistance.

### Example 2

A layered type organic EL element was produced in the manner akin to the manner in example 1 except that the electron injection layer 15a of the first organic EL layer 10a was not formed.

Regarding the resulting organic EL element, the current efficiency was 2.3 cd/A, and the CIE chromaticity was x=0.14 and y=0.10. FIG. 11B illustrates the voltage-current characteristics.

Regarding the organic EL element according to the present example, the voltage to obtain the current density equal to the current density in example 1 was slightly lower than the voltage in example 1, but when the light emission state was examined by using a microscope, light emission on the insulating layer was not observed, and there was no variations in light emission. Therefore, the resulting organic EL element was favorable. In this regard, the emission efficiency was equal to the emission efficiency in example 1.

### Comparative Example 1

A layered organic EL element was produced in the manner akin to the manner in example 1 except that, regarding the intermediate layer 20, Ag and Mg were vapor co-deposited from a tungsten vapor deposition boat at the respective vapor deposition rate of 0.1 Å/s so as to form an intermediate layer 20 having a volume ratio Ag:Mg of 50:50 and a thickness of 2 μm.

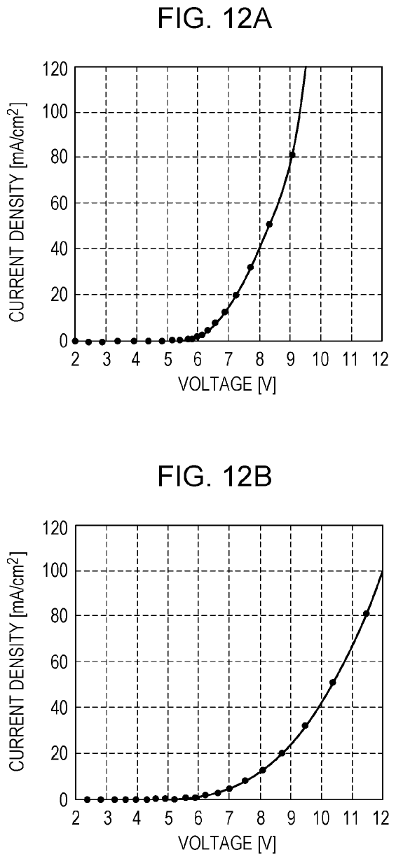

Regarding the resulting organic EL element, the current efficiency was 2.5 cd/A, and the CIE chromaticity was x=0.14 and y=0.11. FIG. 12A illustrates the voltage-current characteristics.

Regarding the organic EL element according to the present comparative example, the voltage to obtain the current density equal to the current density in example 1 was significantly lower than the voltage in example 1, and when the light emission state was examined by using a microscope, light emission on the insulating layer was also observed. When a voltage was applied to only a portion of pixels, light emission of adjacent pixels was observed. It is conjectured that since the intermediate layer 20 was formed of only metals of Ag and Mg, the resistance of the intermediate layer 20 was low, a current passed in the surface direction of the intermediate layer 20, and in the resulting element, light emission on the insulating layer and light emission of adjacent pixels occurred.

### Comparative Example 2

A layered organic EL element was produced in the manner akin to the manner in example 1 except that, regarding the intermediate layer 20, an organic compound ET2 used for the electron transport layer 14a and Mg were vapor co-deposited at the respective vapor deposition rate of 0.1 Å/s so as to form an intermediate layer 20 having a volume ratio ET2:Mg of 50:50 and a thickness of 2 μm.

Regarding the resulting organic EL element, the current efficiency was 1.2 cd/A, and the CIE chromaticity was x=0.14 and y=0.09. FIG. 12B illustrates the voltage-current characteristics.

Regarding the organic EL element according to the present comparative example, the voltage to obtain the current density equal to the current density in example 1 was substantially equal to the voltage in example 1, but the current efficiency was reduced to half the current efficiency in example 1. The reason for this is conjectured to be that the electron injection performance of the electron injection layer 15a and the intermediate layer 20 of the first organic EL layer 10a was not realized, and it is conjectured that the hole passing through the first organic EL layer 10a and the intermediate layer 20 and recombination of the hole and the electron occurring only in the second organic EL layer 10b are indicated. It is conjectured that the cause of the electron injection performance of the intermediate layer 20 not being realized was due to LiF used for the electron injection layer 15a being unable to be reduced. It is conjectured that the cause of being unable to be reduced in spite of Mg being vapor-deposited on LiF was due to a film of Mg not being formed when the intermediate layer 20 was formed since the compatibility between the organic compound ET2 and Mg was low.

### Comparative Example 3

A layered organic EL element was produced in the manner akin to the manner in comparative example 1 except that the electron injection layer 15a of the first organic EL layer 10a was not formed.

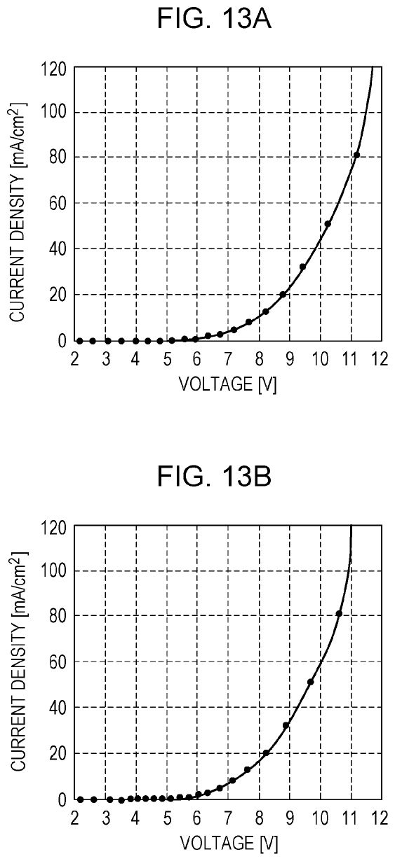

Regarding the resulting organic EL element, the current efficiency was 1.2 cd/A, and the CIE chromaticity was x=0.14 and y=0.10. FIG. 13A illustrates the voltage-current characteristics.

The characteristics of the organic EL element according to the present comparative example were substantially akin to the characteristics in comparative example 2, and the electron injection performance of the intermediate layer 20 in the organic EL element were not realized. It is indicated that when the electron injection layer 15a is not present, the electron injection performance is not realized by only Ag and Mg used for the intermediate layer 20, and an alkali metal compound is necessary.

### Comparative Example 4

A layered organic EL element was produced in the manner akin to the manner in comparative example 2 except that the electron injection layer 15a of the first organic EL layer 10a was not formed.

Regarding the resulting organic EL element, the current efficiency was 1.3 cd/A, and the CIE chromaticity was x=0.14 and y=0.09. FIG. 13B illustrates the voltage-current characteristics.

The characteristics of the organic EL element according to the present comparative example were substantially akin to the characteristics in comparative example 2 and comparative example 3, and the electron injection performance of the intermediate layer 20 in the organic EL element were not realized. It is conjectured that when the electron injection layer 15a is not present, the electron injection performance is not realized by only the organic compound ET2 and Mg used for the intermediate layer 20, and an alkali metal compound is necessary. However, since the same result was obtained in comparative example 2 in which LiF was used for the electron injection layer 15a, there is a high possibility that a film of Mg was not formed due to the compatibility between the organic compound ET2 and Mg being low.

### Example 3

The electron injection layer 15a of the first organic EL layer 10a was formed of KF, and KF was also used for the alkali metal compound used for forming the intermediate layer 20. In addition, ET5 was used for the electron transport layers 14a and 14b, and the thickness was set to be 10 nm. A layered organic EL element was produced in the manner akin to the manner in example 1 except for the above.

When the light emission state of the resulting organic EL element was examined by using a microscope, light emission on the insulating layer was not observed, and there was no variations in light emission. Therefore, the resulting organic EL element was favorable. In this regard, the current efficiency was equal to the current efficiency in example 1.

### Example 4

The metal of group II used for the intermediate layer 20 was Ca, HT19 was used for the hole transport layers 12a and 12b, and the thickness was set to be 3 nm. A layered organic EL element was produced in the manner akin to the manner in example 1 except for the above. There was no significant differences from example 1 except that the supplied electric power was increased due to a high vapor deposition temperature of Ca.

When the light emission state of the resulting organic EL element was examined by using a microscope, light emission on the insulating layer was not observed, and there was no variations in light emission. Therefore, the resulting organic EL element was favorable. In this regard, the current efficiency was equal to the current efficiency in example 1.

### Example 5

A layered organic EL element was produced in the manner akin to the manner in example 1 except that LiF and Mg were vapor co-deposited at the vapor deposition rate of LiF of 0.05 Å/s and the vapor deposition rate of Mg of 0.20 Å/s so as to form an intermediate layer 20 having a volume ratio LiF:Mg of 5:20 and a thickness of 2 μM.

When the light emission state of the resulting organic EL element was examined by using a microscope, light emission on the insulating layer was observed. However, when a voltage was applied to only a portion of pixels, light emission of adjacent pixels was not observed. Therefore, the resulting organic EL element was favorable. In this regard, the current efficiency was equal to the current efficiency in example 1.

### Example 6

The electron injection layer 15a of the first organic EL layer 10a was formed of Liq, and Liq was also used for the alkali metal compound used for forming the intermediate layer 20. In addition, HT19 was used for the hole transport layers 12a and 12b, and the thickness was set to be 3 nm. A layered organic EL element was produced in the manner akin to the manner in example 1 except for the above.

Light emission on the insulating layer was not observed, and there was no variations in light emission. Therefore, the resulting organic EL element was favorable. In this regard, the current efficiency was equal to the current efficiency in example 1.

### Example 7

A layered organic EL element was produced while the light emitting layer 13a of the first organic EL layer 10a emitted two colors of red and green and the light emitting layer 13b of the second organic EL layer 10b emitted a color of blue so as to emit white light in combination. The layer configuration is described in Table 2.

TABLE 2

| | | | Film |
|---|---|---|---|
| | | | thickness |
| Layer | | Material | (nm) |
| Negative electrode 5 | | Mg + Ag | 10 |
| | | mass ratio = | |
| | | Mg:Ag = 50:50 | |
| Second | Electron injection layer 15b | LiF | 1 |
| organic EL | Electron transport layer 14b | ET2 | 20 |
| layer 10b | Hole block layer | ET12 | 21 |
| | Light emitting layer 13b | EM6 + BD9 | 10 |
| | | mass ratio = | |
| | | EM6:BD9 = | |
| | | 99.4:0.6 | |
| | Electron block layer | HT7 | 10 |
| | Hole transport layer 12b | HT2 | 10 |
| | Hole injection layer 11b | HT16 | 7 |
| Intermediate layer 20 | | LiF + Mg | 2000 |
| | | volume ratio = | |
| | | Li/Mg = 50/50 | |
| First | Electron injection layer 15a | LiF | 1 |
| organic EL | Electron transport layer 14a | ET2 | 20 |
| layer 10a | Hole block layer | ET12 | 42 |
| | Light emitting layer 13a | EM1 + RD1 + | 10 |
| | | GD6 mass | |
| | | ratio = | |
| | | EM1:RD1:GD6 = | |
| | | 97.6:0.4:2 | |
| | Electron block layer | HT7 | 10 |
| | Hole transport layer 12a | HT2 | 38 |
| | Hole injection layer 11a | HT16 | 7 |

| | | |
|---|---|---|
| Positive electrode 3 | Ti | 40 |

Regarding the organic EL element according to the present example, light emission from three dopants of red, green, and blue was observed, and it was found that the electron injection performance of the intermediate layer 20 was exerted and that both the first organic EL layer 10a and the second organic EL layer 10b emitted light.

When the light emission state of the resulting organic EL element was examined by using a microscope, light emission on the insulating layer was not observed, and there was no variations in light emission. Therefore, the organic EL element was favorable.

### Example 8

A layered organic EL element was produced in the manner akin to the manner in example 7 except that the electron injection layer 15a of the first organic EL layer 10a was formed of Cs₂CO₃ and that Cs₂CO₃ was also used for the alkali metal compound used for forming the intermediate layer 20. A platinum cell was filled with Cs₂CO₃, and the resulting cell was placed on a tungsten boat and was heated so as to perform vapor deposition. Decomposition such as blackening was not observed after vapor deposition.

Regarding the organic EL element according to the present example, light emission from three dopants of red, green, and blue was also observed in the manner akin to the manner in example 7, and it was found that the electron injection performance of the intermediate layer 20 was exerted and that both the first organic EL layer 10a and the second organic EL layer 10b emitted light.

When the light emission state of the resulting organic EL element was examined by using a microscope, light emission on the insulating layer was not observed, and there was no variations in light emission. Therefore, the resulting organic EL element was favorable.

According to the present disclosure, a layered type organic EL element is provided, the organic EL element including an intermediate layer exerting sufficient electron injection performance and having high resistance, by a vapor co-deposition layer of an easy-to-treat alkali metal compound and a metal of group II serving as the intermediate layer.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-095619, filed Jun. 8, 2021, which is hereby incorporated by reference herein in its entirety.

What is claimed is:

1. An organic electroluminescence element comprising:
a pair of electrodes; and
at least two organic electroluminescence layers that are disposed between the pair of electrodes and that are stacked with an intermediate layer interposed therebetween,
wherein the intermediate layer contains an alkali metal compound, a reduced form of the alkali metal compound, and a metal element of group II of the periodic table.

2. The organic electroluminescence element according to claim 1,
wherein the intermediate layer is a vapor co-deposition layer of the alkali metal compound and the metal element of group II.

3. The organic electroluminescence element according to claim 1,
wherein the intermediate layer is composed of only the alkali metal compound, the reduced form of the alkali metal compound, and the metal element of group II.

4. The organic electroluminescence element according to claim 1,
wherein the organic electroluminescence layer located closer to the intermediate layer than to a positive electrode includes an electron injection layer in contact with the intermediate layer, and
the electron injection layer contains the alkali metal compound and the reduced form of the alkali metal compound contained in the intermediate layer.

5. The organic electroluminescence element according to claim 4,
wherein the electron injection layer is an individual vapor deposition layer of the alkali metal compound.

6. The organic electroluminescence element according to claim 1,
wherein the metal element of group II contained in the intermediate layer is 75% by volume or less.

7. The organic electroluminescence element according to claim 1,
wherein the alkali metal compound is any one of lithium halides and lithium-quinolinol complexes.

8. The organic electroluminescence element according to claim 1,
wherein the alkali metal compound is lithium fluoride or potassium fluoride.

9. The organic electroluminescence element according to claim 1,
wherein the alkali metal compound is cesium carbonate.

10. The organic electroluminescence element according to claim 1,
wherein the metal element of group II is any one of magnesium, calcium, and strontium.

11. The organic electroluminescence element according to claim 1,
wherein the metal element of group II is magnesium.

12. The organic electroluminescence element according to claim 1,
wherein the organic electroluminescence layer located closer to the intermediate layer than to a negative electrode includes a hole injection layer in contact with the intermediate layer.

13. An exposure light source of an electrophotographic image forming apparatus including the organic electroluminescence element according to claim 1.

14. A display apparatus comprising a plurality of pixels,
wherein at least one of the plurality of pixels is the organic electroluminescence element according to claim 1.

15. The display apparatus according to claim 14, comprising a transistor connected to the organic electroluminescence element.

16. An imaging apparatus comprising:
an optical portion including a plurality of lenses;
an imaging element to receive light passed through the optical portion; and
a display portion to display an image imaged by the imaging element,
wherein the display portion includes the organic electroluminescence element according to claim 1.

17. Electronic equipment comprising a display portion including the organic electroluminescence element according to claim 1;
a casing provided with the display portion; and
a communications portion that is disposed in the casing and that communicates with an outside.

18. An illumination apparatus comprising:
a light source including the organic electroluminescence element according to claim 1; and
at least one of a light diffusion portion to pass through light emitted from the light source and an optical filter.

19. A mobile unit comprising:
a lighting appliance including the organic electroluminescence element according to claim 1; and
a bodywork provided with the lighting appliance.
